(19) United States
(12) Patent Application Publication
(10) Pub. No.: US 2022/0215140 A1
(43) Pub. Date: Jul. 7, 2022

(54) PROCESS FOR DETERMINING REAL TIME RISK, RELIABILITY AND LOSS MITIGATION POTENTIAL FOR ULTRA DEEPWATER WELL CONTROL EQUIPMENT USED FOR OFFSHORE DRILLING OPERATIONS

(71) Applicants: Garry Edward Davis, Houston, TX (US); Steven O'Leary, Houston, TX (US)

(72) Inventors: Garry Edward Davis, Houston, TX (US); Steven O'Leary, Houston, TX (US)

(21) Appl. No.: 17/701,545

(22) Filed: Mar. 22, 2022

Related U.S. Application Data
(63) Continuation of application No. 15/943,390, filed on Apr. 2, 2018.
(60) Provisional application No. 62/479,644, filed on Mar. 31, 2017.

(51) Int. Cl. G06F 30/20; G06Q 10/06

(52) U.S. Cl. CPC G06F 30/20; E21B 7/12; G06Q 10/06

(57) ABSTRACT

A risk/reliability assessment tool for ultra-deepwater well control equipment used for offshore drilling operations is disclosed. Embodiments take into consideration all of the processes required for competent risk/reliability assessment for loss mitigation. In an illustrative embodiment, the system provides a simulation tool which evaluates equipment components and simulates the various failure modes for each component and the effect on the other components in the equipment being evaluated. An automated reporting tool quickly identifies components, failure modes for components, and troubleshooting information.

### CROSS REFERENCE TO RELATED APPLICATIONS

This application claims benefit under 35 U.S.C. § 119(e) of U.S. Non-Provisional application Ser. No. 15/943,390, filed Apr. 2, 2018, which claimed benefit from U.S. Provisional Application No. 62/479,644 filed Mar. 31, 2017, which are hereby incorporated by reference herein in its entirety.

### BACKGROUND

The embodiments herein relate generally to boring systems and more particularly, to a process for determining real time risk, reliability and loss mitigation potential for ultra-deepwater well control equipment used for offshore drilling operations.

Offshore Drilling operations employ Subsea Well Control Equipment. When this equipment has any form of operational degradation it requires a full system capability and reliability assessment to be completed. A case document must be submitted to any global regulator as a petition to remain in service or secure the well and pull the equipment to the surface for repairs. This process has traditionally taken days or even weeks to complete and threatens the schedule and profitability of drilling operations. The major oil and gas operators suffer great safety, risk, operational and financial losses during these time periods using the traditional methods for assessment and case submission.

Operators and drilling contractors often are forced unnecessarily to suspend operations and pull their well control equipment back to the surface for repairs because they cannot articulate a compelling case to regulators based on the technical facts. Suspending operations and pulling the equipment back to the surface sometimes possesses a greater threat to the operational safety or environmental protection than remaining in service.

Current systems or methods are post-failure based and only address one of the processes required at a time and are subject to significant variations of outcomes (unpredictable results). In addition, other systems or methods are based on subjective opinion rather than a full technical or engineering evaluation. All typically used evaluations today are subject to human emotion and perceived pressures which adds to the confusion and the length of time it takes to generate action plans and final decisions, which leads to unpredictable results. The systems, processes or tools used today cannot be validated because they are fragmented and inconsistent in their delivery.

Some tools used in industry are dismissed post-delivery of their output because they did not deliver the desired outcome of the assessment. Forcing the loss mitigation to be completed using more traditional and time-consuming methods for assessment. It is problematic for the industry to have a tool that can be ignored because of known issues. Still yet, conventional processes can be over assessed and still miss the technical attributes of the system being evaluated. Embodiments of the disclosed invention solve these problems.

### SUMMARY

In one aspect of the subject technology, a process performed by a computing device simulating risk and loss mitigation in well control equipment for ultra-deepwater drilling, displayed in a user interface system comprises displaying a connection of components in the well control equipment displayed across a plurality of user interface modules; receiving a user selection of one of the components; running a simulation by the computing device evaluating the failure mode for the user selected component; displaying a simulated effect of the user selected component in the failure mode; displaying effects on other components connected to the user selected component in the failure mode; and providing a risk assessment of the evaluated failure mode for the user selected component and for the other components connected to the user selected component.

In another aspect, a computer program product simulating risk and loss mitigation in well control equipment for ultra-deepwater drilling, displayed in a user interface system, comprises a non-transitory computer readable storage medium having computer readable program code embodied therewith. The computer readable program code is configured by a processor to: display a connection of components in the well control equipment displayed across a plurality of user interface modules; receive a user selection of one of the components; run a simulation by the computing device evaluating the failure mode for the user selected component; display a simulated effect of the user selected component in the failure mode; display effects on other components connected to the user selected component in the failure mode; and provide a risk assessment of the evaluated failure mode for the user selected component and for the other components connected to the user selected component.

In yet another aspect, a user interface system for simulating risk and loss mitigation in well control equipment for ultra-deepwater drilling, is disclosed wherein the user interface system is configured to: display a connection of components in the well control equipment displayed across a plurality of user interface modules in the user interface system; receive a user selection of one of the components in a first user interface module; run a simulation by the computing device evaluating the failure mode for the user selected component; display a simulated effect of the user selected component in the failure mode on the first user interface module; display effects on other components connected to the user selected component in the failure mode; and provide a risk assessment of the evaluated failure mode for the user selected component and for the other components connected to the user selected component

### BRIEF DESCRIPTION OF THE FIGURES

The detailed description of some embodiments of the invention is made below with reference to the accompanying figures, wherein like numerals represent corresponding parts of the figures.

FIG. 1 is a user interface (UI) banner for a simulated risk assessment user interface for well control equipment according to an embodiment of the subject disclosure.

FIG. 2 is an enlarged view of well control components connected together across two different user interface modules and a jump link that switches the view from one component to the other component according to an embodiment of the subject disclosure.

FIGS. 3A, 3B, 3C, and 3D are a variety of user interface modules with hydraulically connected components connected between the UI modules, navigable to each other via jump links according to an embodiment of the subject disclosure.

FIG. 4 is a menu of UI modules displayable on various Uls of the UI system according to an embodiment of the subject disclosure.

FIG. 5 is an auxiliary panel UI module according to an embodiment of the subject disclosure.

FIG. 6 is a stack panel UI module according to an embodiment of the subject disclosure.

FIG. 7 is a regulators panel UI module according to an embodiment of the subject disclosure.

FIG. 8 is a meters panel UI module according to an embodiment of the subject disclosure.

FIG. 9 is a gages panel UI module according to an embodiment of the subject disclosure.

FIG. 10 is a miscellaneous functions panel UI module according to an embodiment of the subject disclosure.

FIG. 11 is a diagrammatic view of hydraulically connected component relationships between multiple UI modules according to an embodiment of the subject disclosure.

FIG. 12 is a UI banner home menu with selectable functions for triggering simulations in the well control system according to an embodiment of the subject disclosure.

FIG. 13 is the banner of FIG. 12 with a view tab of functions displayed.

FIG. 14 is a diagrammatic view depicting animated state changes in a selected component activated to simulate a failure mode according to an embodiment of the subject disclosure.

FIG. 15 is a sectional view of a UI module showing simulated components with a failed component highlighted using a highlighting tool according to an embodiment of the subject disclosure.

FIG. 16 is a block diagram of a UI module showing connected components with a failed component highlighted using a highlighting tool according to an embodiment of the subject disclosure.

FIG. 17 is an enlarged schematic view of components with selectable associated identifications that provide a menu option for triggering an autogenerated report according to an embodiment of the subject disclosure.

FIG. 18 is a screenshot of an autogenerated risk assessment and contingency plan report for a simulated induced failure of the well control system according to an embodiment of the subject disclosure.

FIG. 19 is a block diagram of component connections in the well control system as stored in a file according to an embodiment of the subject disclosure.

FIG. 20 is a screenshot of a UI module showing a section of the well control system and a pop-up menu of actions associated with a selected component according to an embodiment of the subject disclosure.

FIG. 21 is a flowchart of a process for simulating risk and loss mitigation in well control equipment for ultra-deepwater drilling, displayed in a user interface system, according to an embodiment of the subject disclosure.

### DETAILED DESCRIPTION OF CERTAIN EMBODIMENTS

In general, embodiments of the present disclosure provide a risk/reliability assessment simulator tool for ultra-deepwater well control equipment used for offshore drilling operations. Aspects of the system take into consideration all of the processes required for loss mitigation using risk/reliability assessment processes. In an exemplary embodiment, the system provides a simulation tool which, through a program module of user interfaces, evaluates equipment and simulates the various potential results from operating the equipment in its current state or under proposed operating conditions.

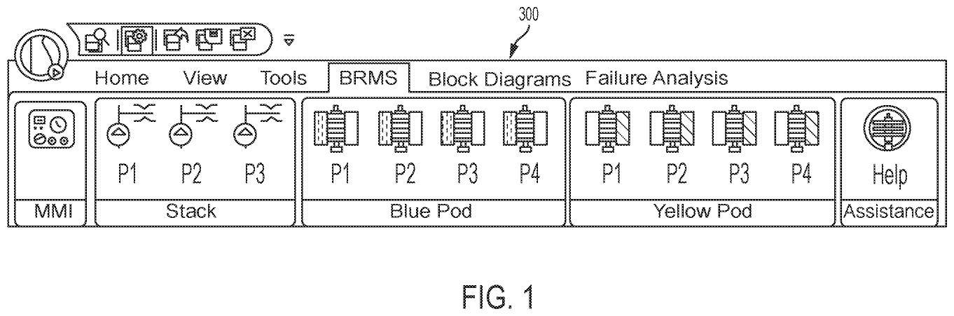

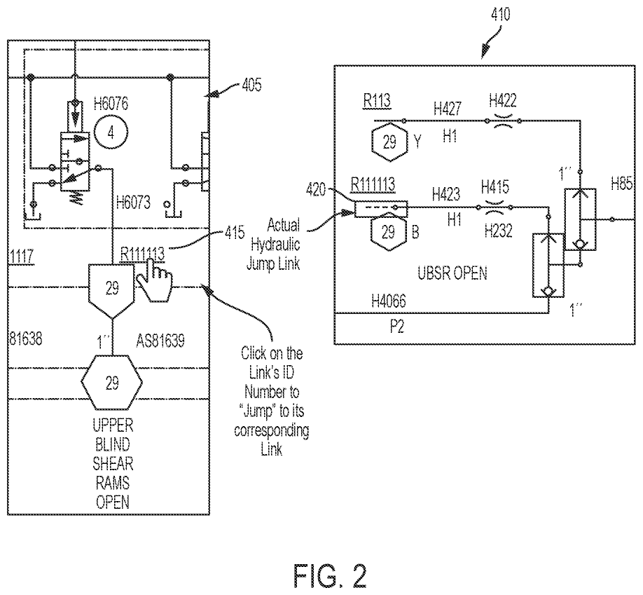

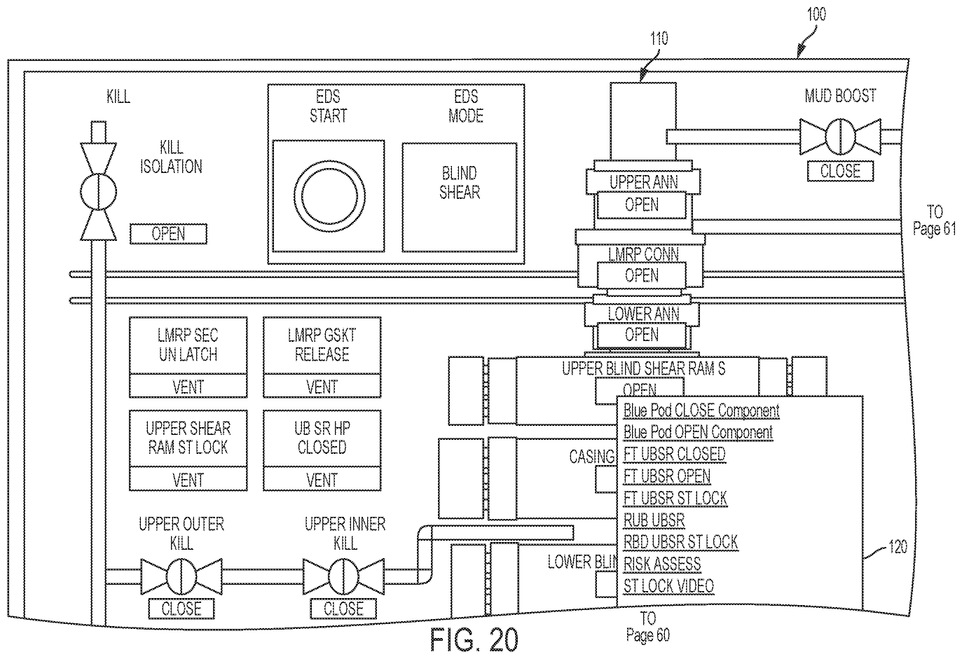

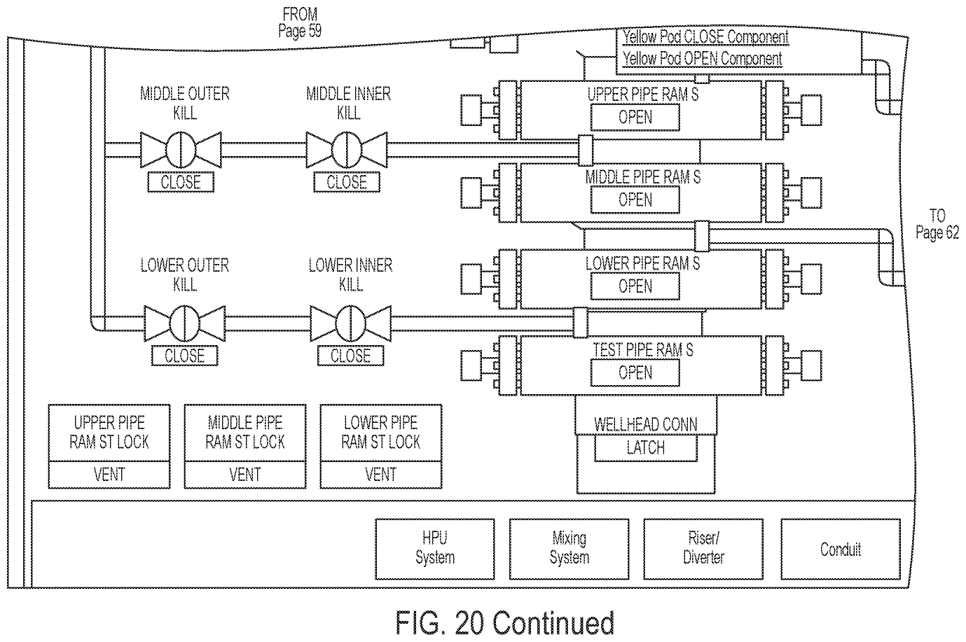

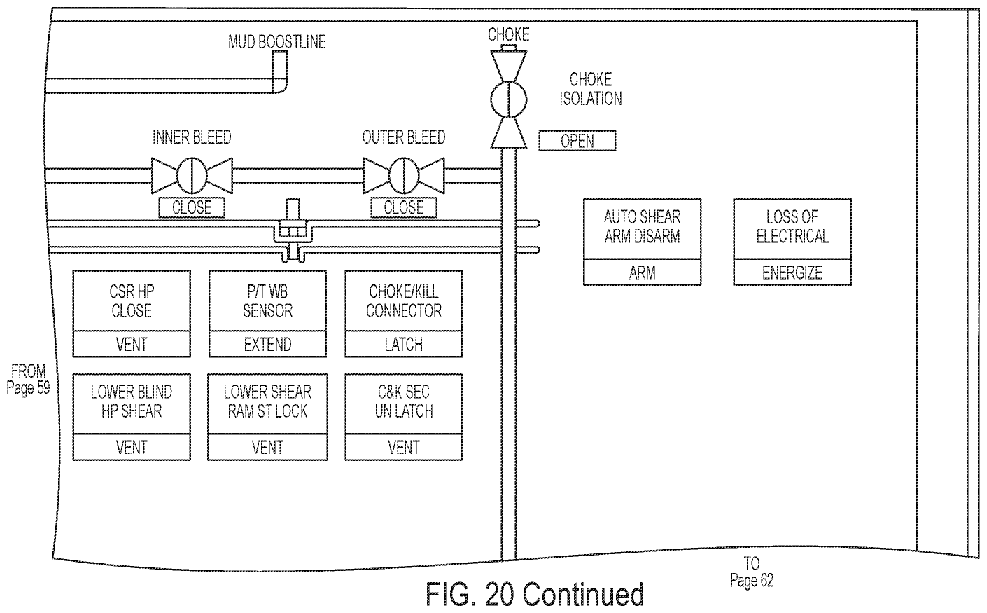

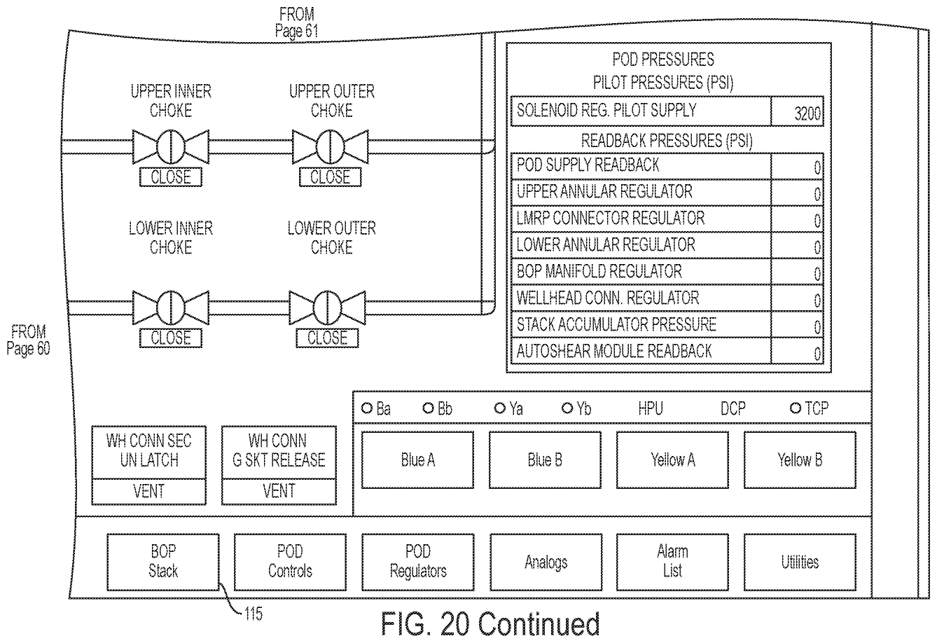

Referring first to FIG. 20 (which shows an example of a UI display 100 of a simulated assessment for a piece of equipment 110) and 21 (which shows a flowchart of a method 200 of simulating failure modes and determining risk impact on a system), features of the subject technology will be discussed which will be explained in further detail by reference to FIGS. 1-19 below.

Referring to FIG. 20, in one embodiment, aspects of the simulation system are applied to a controlled Blowout Preventer (BOP) simulator (accessed via selectable module 115) (which may be an exact replicate of the system). However, as will be understood, the subject technology described may be applied to other well control equipment configurations. As will be appreciated, the features of the system graphically display failure modes to various system parts and provide visual results and interrelationships between elements connected to the failed part. So, assistance is given to users, from troubleshooting and fault finding, to communicating the technical facts of the case for all decision makers, in an easy to understand UI report.

The simulator system generates on the UI display 100, a simulation of the piece of equipment 110 connected to multiple other elements of the well control equipment system. The back-end of the system may store metadata associated with each element in the well control system. More importantly, the simulator system may, through artificial intelligence and/or stored data, simulate resultant effects on the operating capability of elements in the well control system in response to simulated induced failure on one or more user selected elements of the well control system.

As may be appreciated, well control systems may be large-scale, heavily connected systems with many mechanical elements interconnected together. As there may be many points of failure, testing and predicting failures through simulation before a system is operated may prevent catastrophic failures. Aspects of the subject disclosure provide multiple UI windows which show a failure induced in one part of the well control system and the results along one or more connected lines in other UI windows displaying other areas of the well control system. Some embodiments organize the system according to control pods which may be differentiated from each other by color or other visual distinction. As will be seen, since control pods are typically running parallel or in close proximity, and eventually in connection to each other in the real world, aspects of the system allow a user to quickly trace issues down a pod line and into an element affected in the adjoining pod.

In an exemplary embodiment, the UI display generates the well control system elements with selectable features that either directly change the element's status (for example, switch a valve from open to closed), which may be seen move visually on screen or may trigger a menu 120 of actions related to the element, which may trigger simulation of resultant effects on screen. Although it is not realistically or reasonably possible to show the moving aspects of the simulator system in static drawings amongst various areas of the well control system, one feature of the system displays in motion, changes occurring along a pod line as one element is activated for failure, stress, or other operating condition. The elements connected to the element under test respond in series according to, (in one embodiment), stored fault tree analysis files which predict the effect of the first element in series, then the aggregate effect on subsequent elements in series with the element under test. The UI 100 may visually display the effects of each element along the line as changes occur in the system.

For elements not viewable in a current UI display, an exemplary embodiment includes a quick link function that allows the user to jump to different areas of the well control system during a simulation. As will be shown in detail below, each element may be designated with a reference number. A jump link may be displayed next to the element and selection of the jump link may switch the UI to display another area of the system and elements connected to the source element of the jump link.

As will be appreciated, as changes to the system occur during a test, aspects of the embodiments allow for and may generate simulator videos which can be made of the system faults and failures and which may be submitted as evidence to regulators for their consideration eliminating the need for regulators to do a manual P&ID (piping and instrumentation diagram) technical review (which is typically out of their core skill set capability). As will be appreciated, considerable time is saved by automating the results for regulators and features described herein will generate substantially improved accuracy in the evaluation of systems when compared to the manual P&ID approach. Aspects reduce confusion and the time needed for a thorough exam of the technical facts of the case being submitted. The risk assessment process has been automated through software programming so the end user only needs to know a component identification number/label on the simulated component or component(s) they have identified as the root cause. The failure mode information is input into the risk assessment form and all other technical information from troubleshooting to a full system specific contingency plan auto populates into a report for review and action. As will be appreciated, these features are nonexistent in any offshore drilling operation today.

The system has all loss mitigation tools embedded into the simulator and are retrievable on at will and on demand. These are reliability block diagrams, family of function block diagrams, fault trees, animated component functional videos, rapid navigation links and troubleshooting guide.

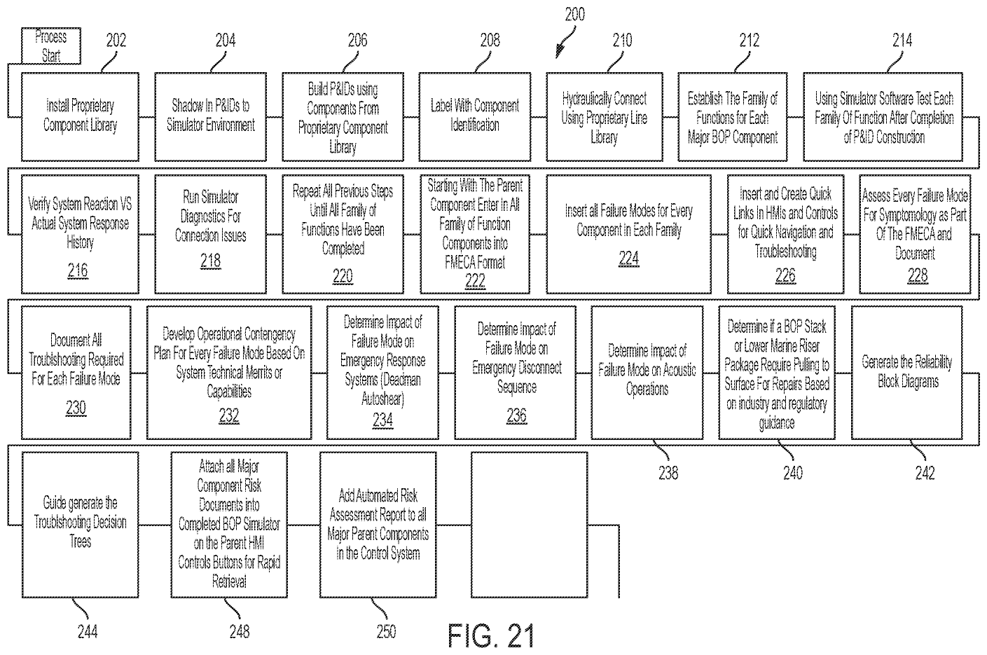

Referring now to FIG. 21, a method 200 of simulating failure modes and determining risk impact on a system is shown according to an exemplary embodiment. In one aspect, the method 200 provides and end result where a user when wanting to see what the failure mode results for an identified component will provide by simulation. The results in are provided as a result of the failure mode selected. In some embodiments, fault and risk assessment tools are developed and standardized for a specific system, due to the fact that every system is unique and the behavior of parts is predicted for the control equipment system. This provides accuracy of technical assessment and reporting capabilities.

As a preliminary step prior to actual simulation, a proprietary library of components may be installed 202 for the control equipment to be simulated. P&IDs may be shadowed 204 into the simulator environment. P&IDs may be built 206 using components from the library. Each component in the system may be labeled 208 with identification. The components in the system being simulated may be virtually assembled 210 by virtual hydraulic lines from lines stored in the library. In a stored file, the family of functions for each component may be established 212. After P&ID construction, each family of functions may be tested 214 using simulator software. By referencing a stored history of actual test results for element parts, the simulated reaction may be compared 216 to actual verified system response results. Simulator diagnostics may be run 218 to identify connection issues. The process may be repeated 220 for steps 202-218 for each family of functions. Starting with the parent component for a family of functions, all family of function components may be entered 222 into a reporting format (for example, FMECA). All failure modes for every component may be stored 224 for each family.

The following will be described in terms on a UI display generated for simulating the control equipment under operation and induced failure modes. Quick links (also sometimes referred to as “jump links”) may be created and inserted 226 in association with each element part in the system displayed in the UI. The creation process may refer to metadata files which state which elements are connected to which other elements. A quick link may identify the elements connected to the element receiving the quick link and include data indicating what other windows/displays show the connected elements and at what position in the window the element is located. A quick link (jump link) is generated within the software by drawing a hydraulic line between components. A command to switch the view between the two components is attached to the link. At this point, the software changes the line into two “links”. One link is cut and moved to another page and inserted where the line needs to “jump” to in order to make hydraulic flow.

For a selected element in the control system being simulated, and for a selected failure mode, the selected elements and connected elements are assessed 228 for symptomology and effect on connected elements. Each failure mode may be documented 230. At the onset of the project, a full list of all components is generated from the software bill of material. That is moved to a spreadsheet or other tracking tool (for example, tables, charts, etc.) and sorted by nomenclature. A “code” may be assigned to each group of components. For example, even though there may be 12 different types of valves, they may all fail in the same manner by either not shifting, loss of fluid, etc. So, each of them may receive the same codename. An operational contingency plan may be developed 232 for every failure mode assessed based on technical merits or capabilities. During simulation, a component under assessment may be changed to the failure state and the stored files may be referenced to determine an outcome. The assessment of every failure mode identified in the control system as a whole may be evaluated. The impact of failure modes on emergency response systems may be determined 234 to ensure it does not affect the Deadman Autoshear automated emergency system. If identified within the assessment as a “YES”, then the failure mode does impact the Autoshear system and if “NO” then there is no impact from the failure mode being assessed. This is to clarify that the failure mode being assessed does or does not impact emergency capabilities. If this system is impacted by any failure mode, the criticality of the failure is adjusted accordingly to match the severity of the impact. Usually a higher criticality with more severe impacts on emergency capabilities forces a re-evaluation of criticality.

An example of Deadman Autoshear in the system is described under the condition of Simultaneous Loss of Hydraulic Power and Electric Power. When the selected MUX pod is hydraulically and electrically active and the Electrohydraulic Backup System or Deadman Autoshear is in the “Arm” mode, the pilot pressure from the pilot line opens the dual action “Arm” isolation directional control valve (DCV). This allows fluid pressure from the BOP dedicated stack-mounted shear emergency accumulator banks to pressurize the system. A pilot line controls the “Loss of Hydraulic Supply” DCV, and a separate pilot line controls the “Loss of Electric Supply” DCV. Both DCVs are connected in series to control the shear supply pressure; therefore, both DCV pilot pressures have to be lost before the valves will open. If the hydraulic supply pressure and the electric power supply to both MUX pods fail, the following sequence will occur: When in the “Arm” mode, the “Arm/Disarm” SPM valve will remain open. (Loss of pilot pressure from pilot lines does not affect the position of the double-acting DCVs; it will remain in the open position when electric power to the MUX pod pilot valve is lost.) The “Loss of Hydraulic Supply” DCV and the “Loss of Electric Power” DCV together will allow operating pressure to pressurize the emergency response system and fire the Deadman which usually is sequenced as; 1) HP supply un-isolated. 2) Casing Shear Rams are activated; the timing circuit closes the Blind shear rams and 3) all inner choke and kill valves are hydraulically closed to secure the well.

In step 236, during the assessment of every failure mode identified in the system as a whole must be evaluated to ensure it does not affect the Emergency Disconnect Sequence programmed automated emergency system and identified within the assessment as a “YES” it does impact the EDS system or “NO” meaning no impact from the failure mode being assessed. This is to clarify that the failure mode being assessed does or does not impact EDS capabilities. If this system is impacted by any failure mode, the criticality of the failure is adjusted accordingly to match the severity of the impact! Usually a higher criticality with more severe impacts on emergency capabilities forces a re-evaluation of criticality! There may be as many as 8 different programmable EDS sequences that can be assigned. Each may be assessed individually to ensure that there is no impact from the failure mode being assessed.

In step 238, the assessment of every failure mode identified in the system as a whole must be evaluated to ensure it does not affect the Acoustic remotely controlled tertiary emergency system and identified within the assessment as a “YES” it does impact the acoustic system or “NO” meaning no impact from the failure mode being assessed. This is to clarify that the failure mode being assessed does or does not impact acoustic capabilities. If this system is impacted by any failure mode, the criticality of the failure is adjusted accordingly to match the severity of the impact! Usually a higher criticality with more severe impacts on emergency capabilities forces a re-evaluation of criticality! The acoustic systems are usually constructed to manage well control in the event of the loss of control via the primary or secondary controls capabilities, this system is not mandatory but if installed can have significant impacts on well control equipment capabilities, the effects of any failures associated with this system can have a significant impact on the reliability of the well control equipment as a whole.

Below is an example of a hypothetical programmed sequence and the actions the system will take during the firing of the EDS.

The Acoustic Backup System consists of both surface and stack-mounted components. The Original Equipment Manufacturer (OEM) furnishes the stack-mounted electrohydraulic assembly; others may supply the surface components and subsea electronic assemblies. The stack-mounted Acoustic pod is an acoustically controlled, electrohydraulic unit located on the lower (BOP) Stack. The Acoustic Control pod may be designed to activate the following BOP stack functions in the event normal control from the MUX Pods are inoperative:

Riser Connector Primary Unlock

Riser Connector Secondary Unlock

All Stabs Retract

Upper Blind Shear Rams Close

Casing Shear Rams Close

Lower Blind Shear Rams Close

Upper Pipe Rams Close

Lower Pipe Rams Close

Arm and Disarm

All of these functions are directly related to either primary well control capability or an EDS Emergency Disconnect Sequence.

In step 240, every failure mode identified in the system as a whole must be evaluated to ensure it does not affect the entire systems capability to maintain its in service status. This is identified within the assessment as a “YES”, a stack or LMRP Pull is required, or “NO” meaning no impact from the failure mode being assessed has not degraded capabilities to a point that industry and/or regulatory minimum capabilities have been breached. This is to clarify that the failure mode being assessed does or does not impact a clear and well-studied minimum capability the system must maintain to remain in service.

The method may additionally generate 242 reliability block diagrams. In step 244, some embodiments generate troubleshooting decision trees that may be used by the system to provide guidance on failure modes of elements. The process may build a system library of all completed simulations and results. In step 248, all of the needed risk communication documents including the report form must be capable of being retrieved on demand for rapid assessment. For every function all of the relevant documents pertaining directly to that function may be attached via a quick link directly to the function button on the HMIs (Human Machine Interface) (user interface shown in FIG. 20), these documents include Reliability Block Diagrams, Fault Trees, any required technical documentation and any requested media types such as animation of how the function is supposed to work, the risk assessment report and quick hyperlinks to the components that are controlled by the HMIs. An automated risk assessment report may be added 250 to all parent components in the control system which are easily accessible by menu selection in the UI. This is a key element in rapid risk assessment and response capabilities. The BOP Controls simulator is the primary failure mode communication device to simplify the risk assessment process.

The following describes specific features of the UI 100 and additional features and windows in the simulator system of the present invention.

Referring now to FIG. 1, in an exemplary embodiment, the simulator contains for example, 12 different modules. In some embodiments of the UI, these are available across the banner 300 at the top of the page under the “BRMS” tab. The banner 300 is separated into 5 frames identified as the MMI, Stack, Blue Pod, Yellow Pod and Assistance. Each icon in the frames will bring up an individual module. “Blue Pod” and “Yellow Pod” refer to different control pods that function concurrently in the well control system being assesses for risk mitigation. In general, all user interface functions are activated or read from one of the five HMI panels under the MMI tab. The output signals from the buttons are linked to “Solenoids” (virtual representation of an electromechanical valve in the system between elements) in the Yellow and Blue Pods. The signal generated by selecting a button will cause the solenoid to shift (P1 for LMRP Functions; P2 for Stack Functions on each of the Pod documents).

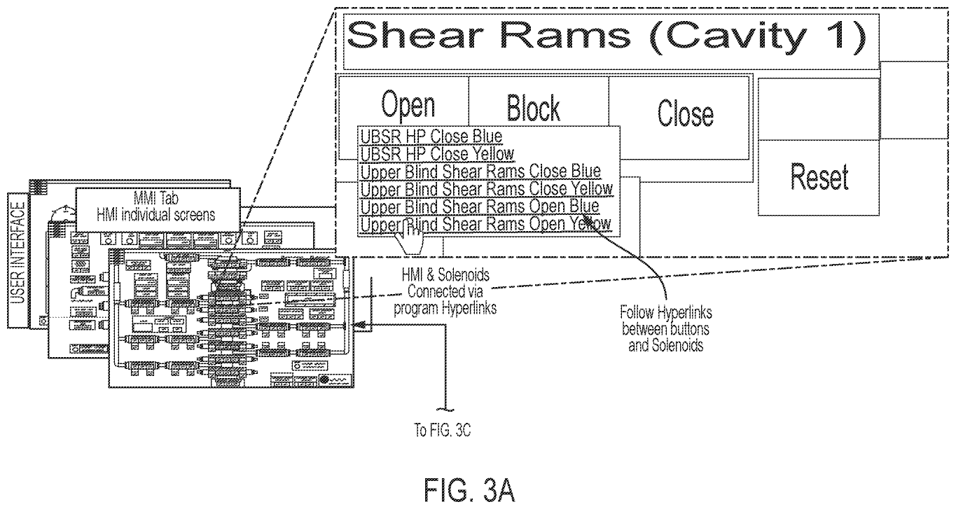

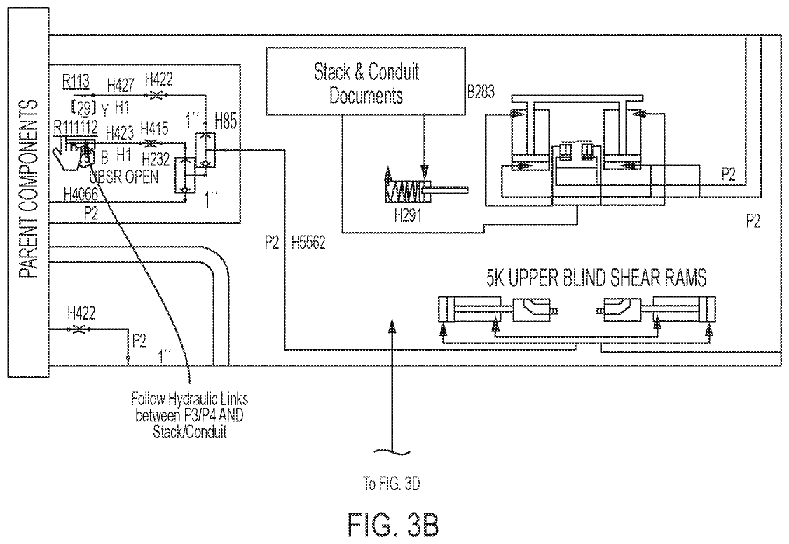

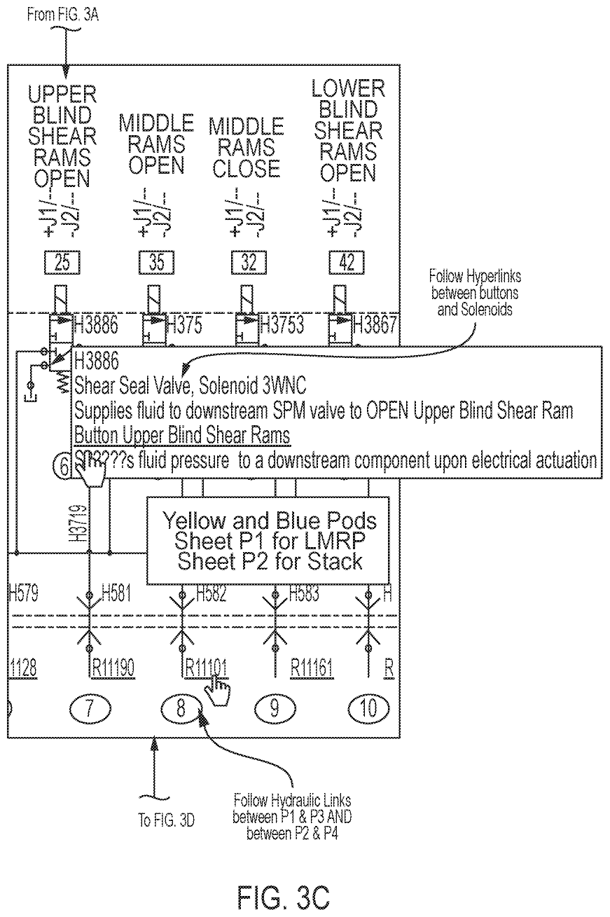

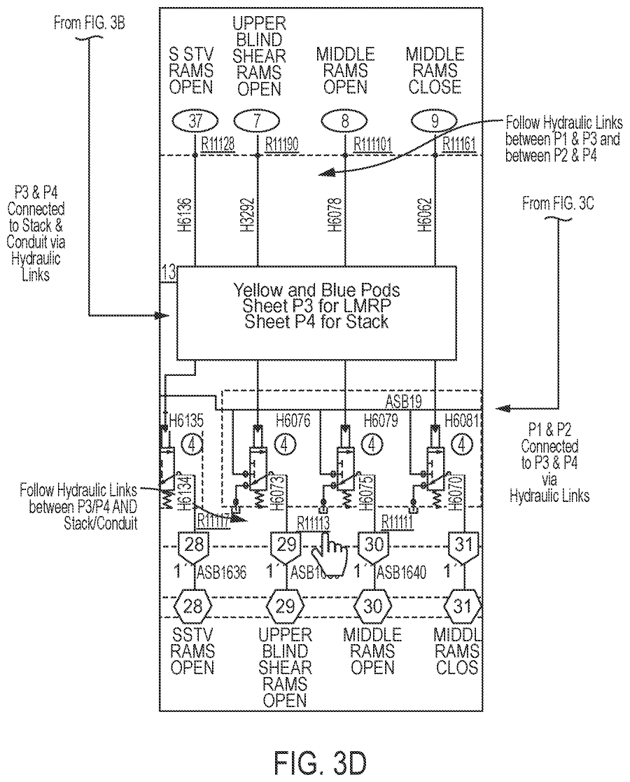

Referring to FIG. 2, sections of a UI are shown, enlarged to show the interconnected relationship between elements across UI modules shown in FIGS. 3A-3D. For example, the hydraulic flow output from the Yellow pod and Blue pod actuated solenoids on P1 and P2 are hydraulically linked to the Pod directional valves; P3 for LMRP and P4 for Stack Functions. These links may sometimes be referred to as “Jump Links” 415 because they cross or jump between UI module displays. In some embodiments, a jump link 415 is shown by an identification number of a corresponding connected element. Clicking on a jump link 415 triggers a background action that switches from the current UI display of the control system to a connected element 420 displayed on another UI display. They behave as if it were a straight hydraulic connection and the users instantly sees the connected element and the impact of the element put into a failure mode. The Pod P3 and P4 valves are connected with hydraulic jump links 415 to components on the stack or conduit valve package. These hydraulic links can be followed back and forth throughout the simulator to see effects all around the control system as shown in FIGS. 3A-3D.

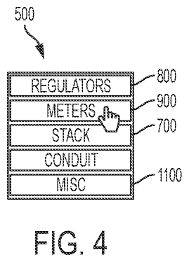

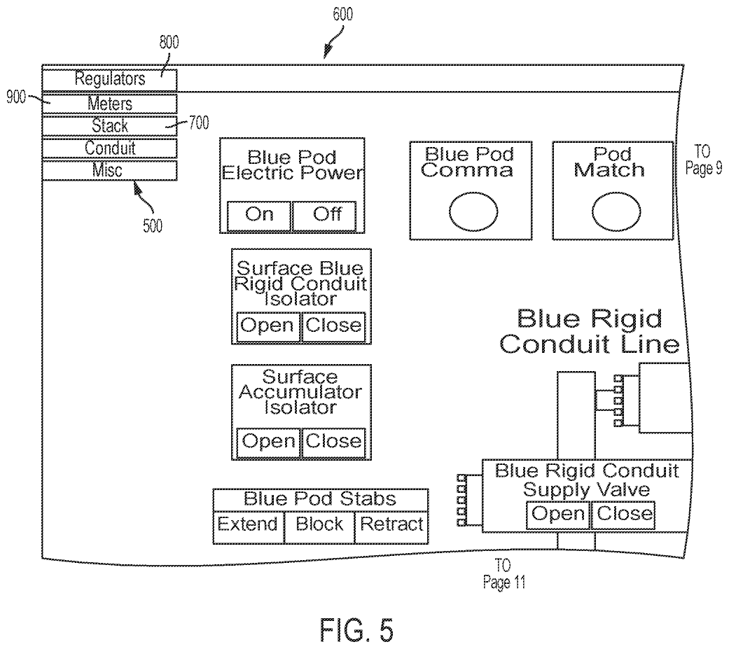

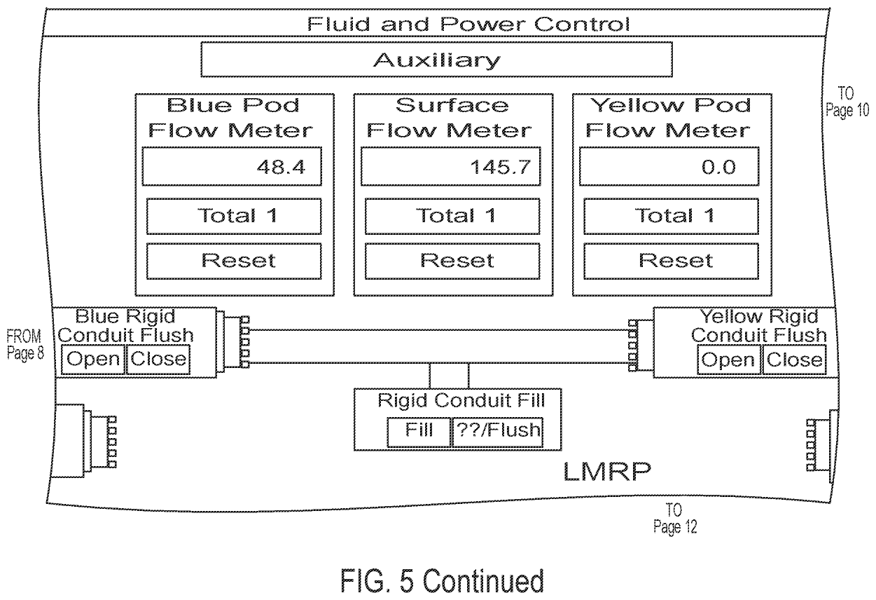

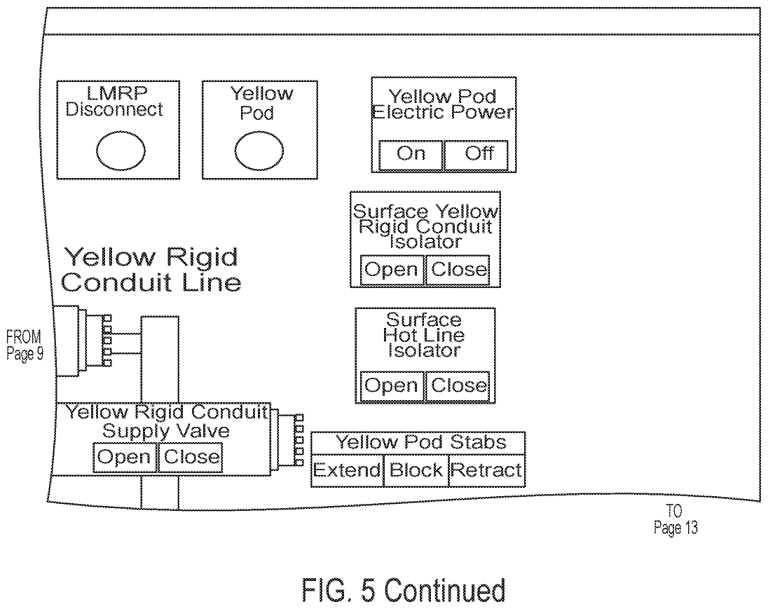

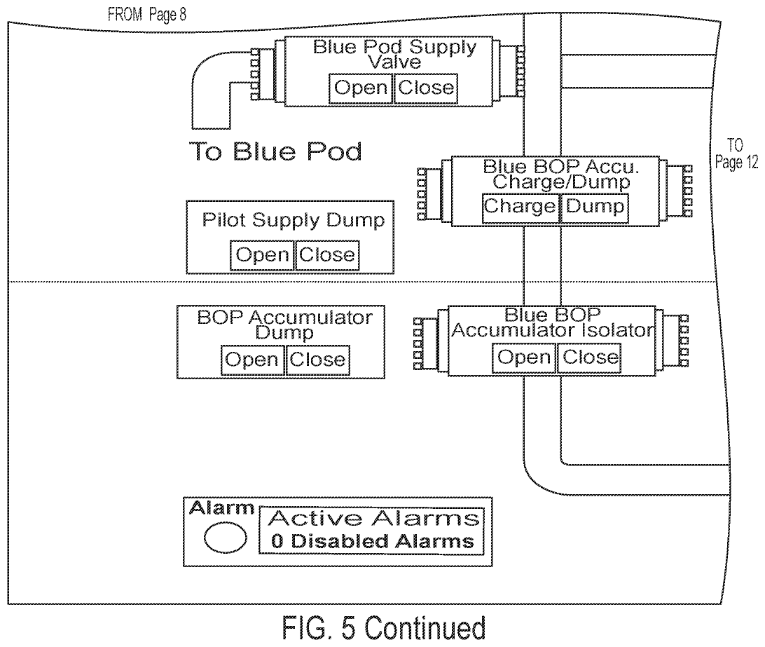

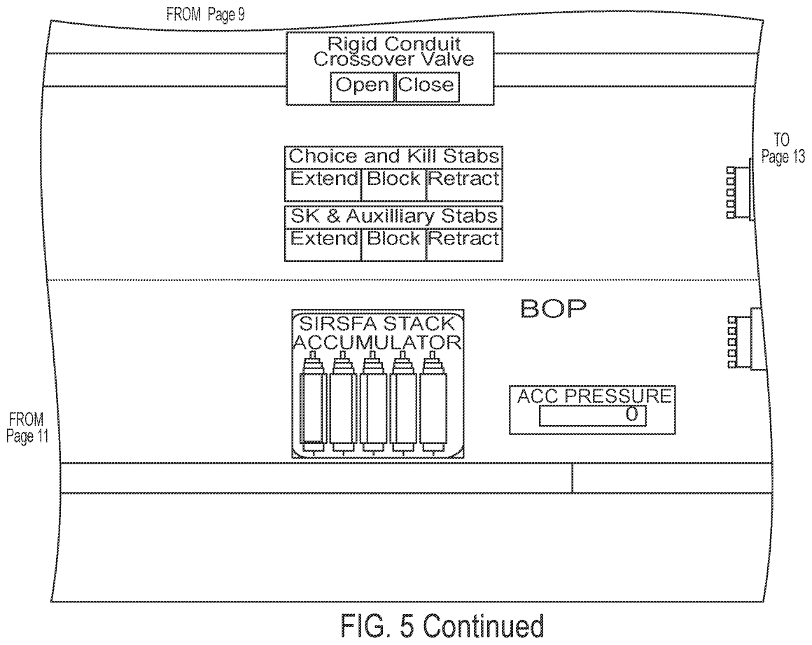

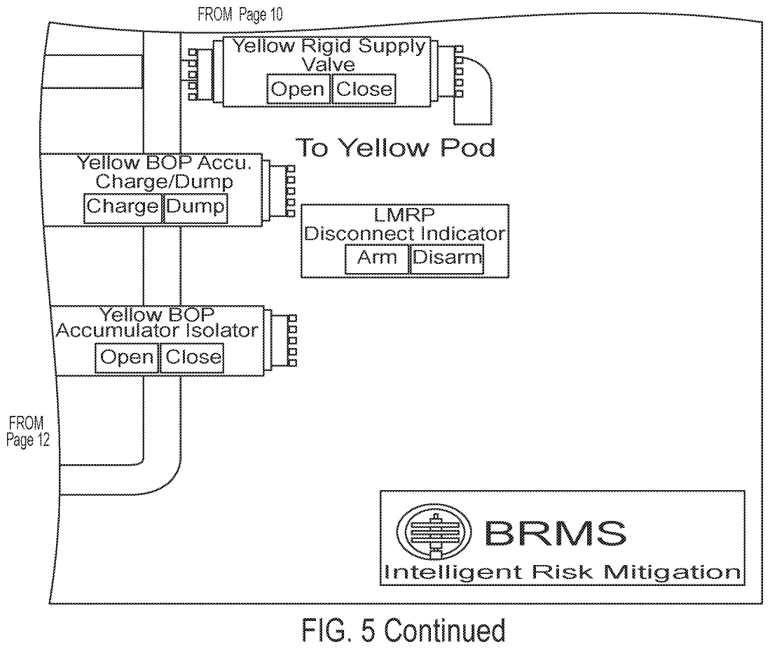

Control panels may be found for example, under the tab MMI. There are five panels, as shown in menu 500 of FIG. 4. In operation they can be seen in one or more UIs (for example, as shown in FIG. 5). These can be navigated between each other by clicking on a button which will take the current MMI window to the corresponding panel. In some embodiments, the panels are laid out on the MMI page in a vertical manner and can also be searched by simply scrolling up and down with the mouse. The HMI panels reflect the panels on the piece of control equipment, however in the simulator, certain functions are inactive. The buttons for the Regulators Increase/Decrease functions are momentary buttons. They will stay engaged for as long as a GUI (for example, a mouse) remains on the button and the left key depressed. Other buttons may be a locked button, in that once they are clicked with the left mouse key, they will remain in that state until another associated button such as block is selected.

Referring now to FIG. 5, an Auxiliary Panel UI 600 is shown according to an exemplary embodiment. The UI 600 contains the control for most Conduit Valve Functions, Pod set up functions and surface functions. As well as functions for the stack accumulators. As will be appreciated, the UI 600 generates easy to access triggerable controls that instantly simulate a cause and effect relationship between elements in the control system. Buttons are assigned to and may be graphically situated on each element in the control system. Selecting a button triggers a response to graphically show what the effect occurs on connected elements in the control system. An exemplary embodiment may show the effects in series so that visually, the user can see how elements down a line are affected by a failure mode induced on a selected element. Table 1 shows examples of how elements in the illustrated control system behave in response to one element being selected to change status per the buttons on the UI 600.

In some embodiments, the process references a stored table that indicates an element status and the effect on the control system. Depending on the element selected, the process references the information associated with the element and triggered status. Table 1 shows an exemplary reference table for the control system depicted. It will be understood that similar elements in other systems may behave differently depending on their connection to other elements in the overall system.

TABLE 1

| | | | Normal |
|---|---|---|---|
| | Unenergized | | Operating |
| Name | State | Information | State |
| Yellow Rigid | Close | If Opened, this valve will vent the yellow conduit | Close |
| Conduit Flush | | through the directional valve controlled by the rigid | |
| Valve | | conduit Fill (See NOTE at end of this table!) | |
| Blue Rigid | Close | If Opened, this valve will vent the blue conduit through | Close |
| Conduit Flush | | the directional valve controlled by the rigid conduit Fill | |
| Valve | | (See NOTE at end of this table!) | |
| Rigid Conduit | Open to | If this valve is actuated, it supplies fluid from the pod | Fill |
| Fill | Vent | to a point in the conduit valve package downstream of | |
| | through | both flush valves. If a flush valve is then opened, this | |
| | Manual | line will fill the conduit up to the pressure set on the | |
| | Valve on | pod manifold regulator. (See NOTE at the end of this | |
| | Stack | table!) | |
| Yellow Rigid | Open | If closed, this valve will block all fluid from the yellow | Open |
| Conduit | | rigid conduit to the pod, however fluid will continue to | |
| Supply Valve | | shift the directional valve to line 19 “Hydraulic Supply | |
| | | to Autoshear Valve”. The Autoshear valve in the stack | |
| | | will not actually shift unless there is fluid from the hot | |
| | | line or other conduit. | |
| Blue Rigid | Open | If closed, this valve will block all fluid from the blue | Open |
| Conduit | | rigid conduit to the pod, however fluid will continue to | |
| Supply Valve | | shift the directional valve to line 19 “Hydraulic Supply | |
| | | to Autoshear Valve”. The Autoshear valve in the stack | |
| | | will not actually shift unless there is fluid from the hot | |
| | | line or other conduit. | |
| Rigid Conduit | Close | Allows communication between the Yellow and Blue | Close |
| Crossover | | Conduit Lines downstream of the filters. (Can cause | |
| Valve | | backflow through filters.) | |
| | | Note: To run the system with the Crossover Valve closed | |
| | | either the Hot Line Open OR both Yellow and Blue Conduits | |
| | | Open MUST be selected. | |
| Yellow Pod | Open | When closed, this valve stops fluid to the Yellow Pod | Open |
| Supply Valve | | 3000 PSI supply (Line 60); stops fluid to the Hydraulic | |
| | | Supply to Autoshear Valve (Line 19) and stops flow to | |
| | | the 5000 PSI Supply to the pod (Line 15). Effectively | |
| | | cutting off ALL hydraulic supply to the Yellow Pod. | |
| Blue Pod | Open | When closed, this valve stops fluid to the Blue Pod | Open |
| Supply Valve | | 3000 PSI supply (Line 60); stops fluid to the Hydraulic | |
| | | Supply to Autoshear Valve (Line 19) and stops flow to | |
| | | the 5000 PSI Supply to the pod (Line 15). Effectively | |
| | | cutting off ALL hydraulic supply to the Blue Pod. | |
| BOP | Dump | When this valve is in Dump position AND the Yellow | Charge |
| Accumulator | | BOP Accumulator Isolator Valve (on stack drawing) is | |
| Charge/Dump | | OPEN; the stack accumulator bottles will vent through | |
| (Yellow) AND | | the manual valve on the stack. When this valve is in | |
| Yellow BOP | | the Charge position AND the Yellow BOP Accumulator | |
| Accumulator | | Isolator Valve is OPEN; the stack accumulator bottles | |
| Isolator Valve | | will be charge from the conduit supply. IF the | |
| | | crossover valve is open, it can be supplied from either | |
| | | conduit. If the crossover valve is closed, only the | |
| | | Yellow Conduit is available to supply the bottles. | |
| BOP | Dump | When this valve is in Dump position AND the Blue BOP | Charge |
| Accumulator | | Accumulator Isolator Valve (on stack drawing) is OPEN; | |
| Charge/Dump | | the stack accumulator bottles will vent through the | |
| (Blue) AND | | manual valve on the stack. When this valve is in the | |
| Blue BOP | | Charge position AND the Blue BOP Accumulator | |
| Accumulator | | Isolator Valve is OPEN; the stack accumulator bottles | |
| Isolator Valve | | will be charged from the conduit supply. IF the | |
| | | crossover valve is open, it can be supplied from either | |
| | | conduit. If the crossover valve is closed, only the Blue | |
| | | Conduit is available to supply the bottles. | |

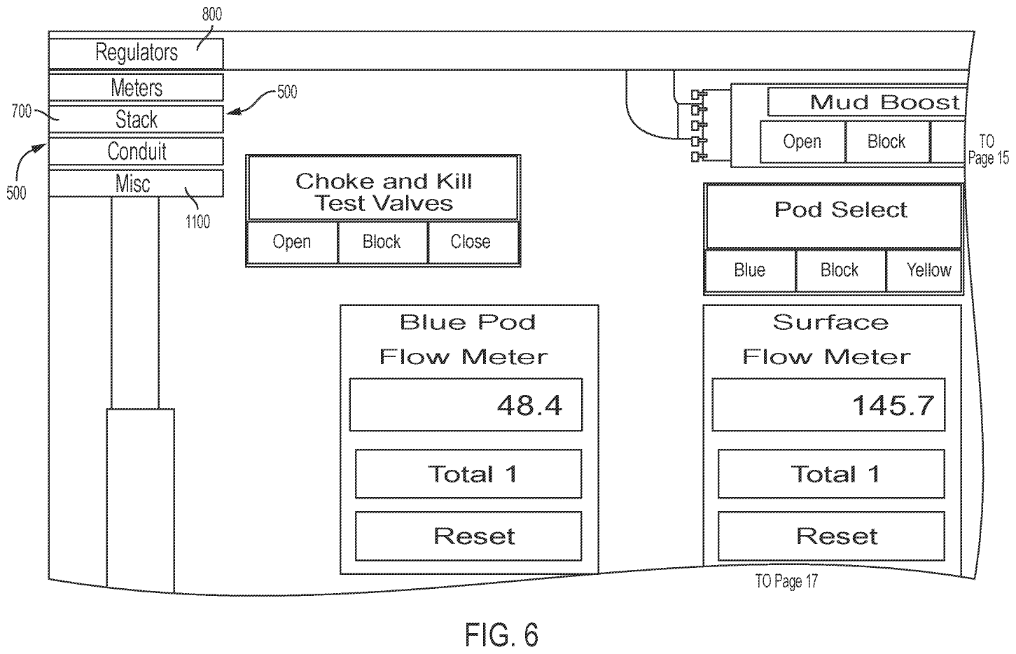

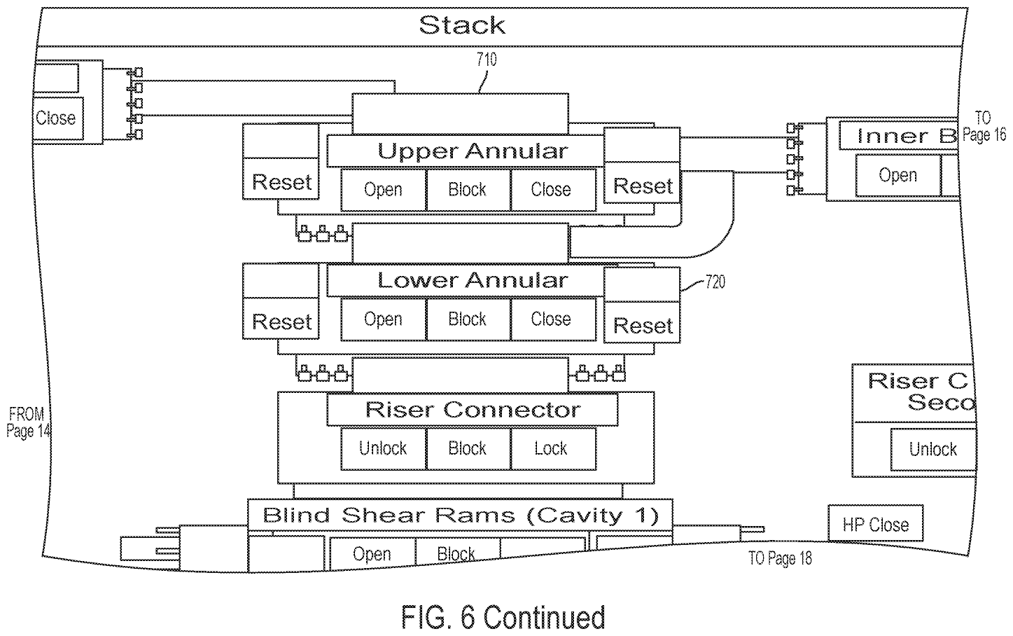

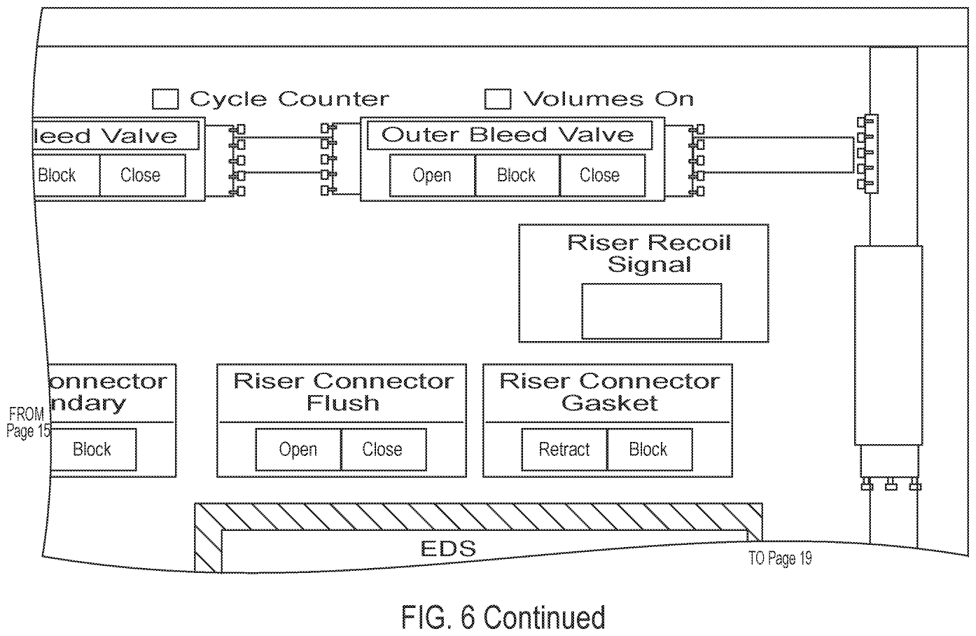

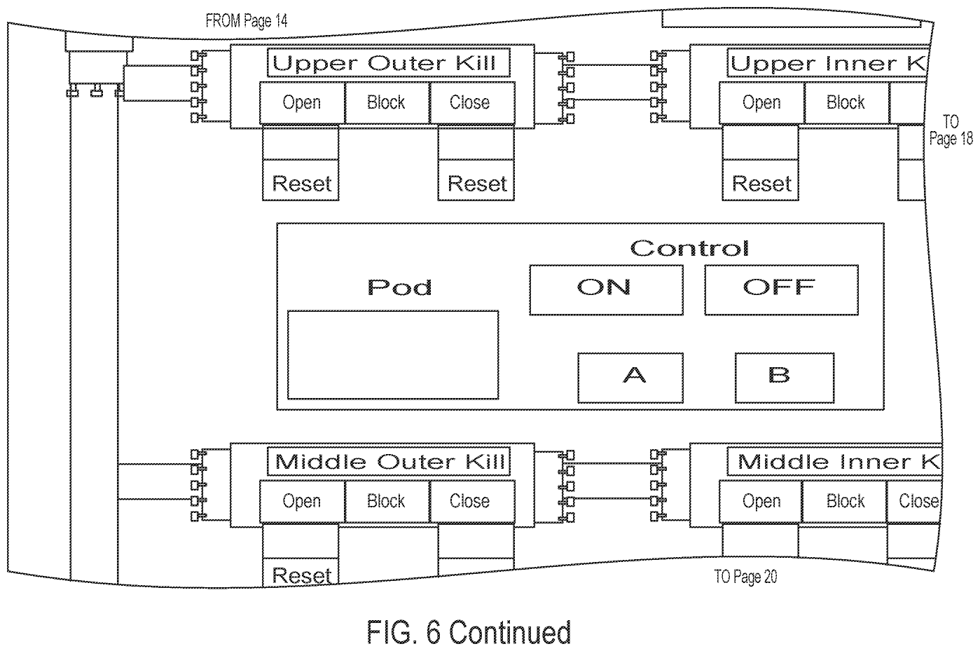

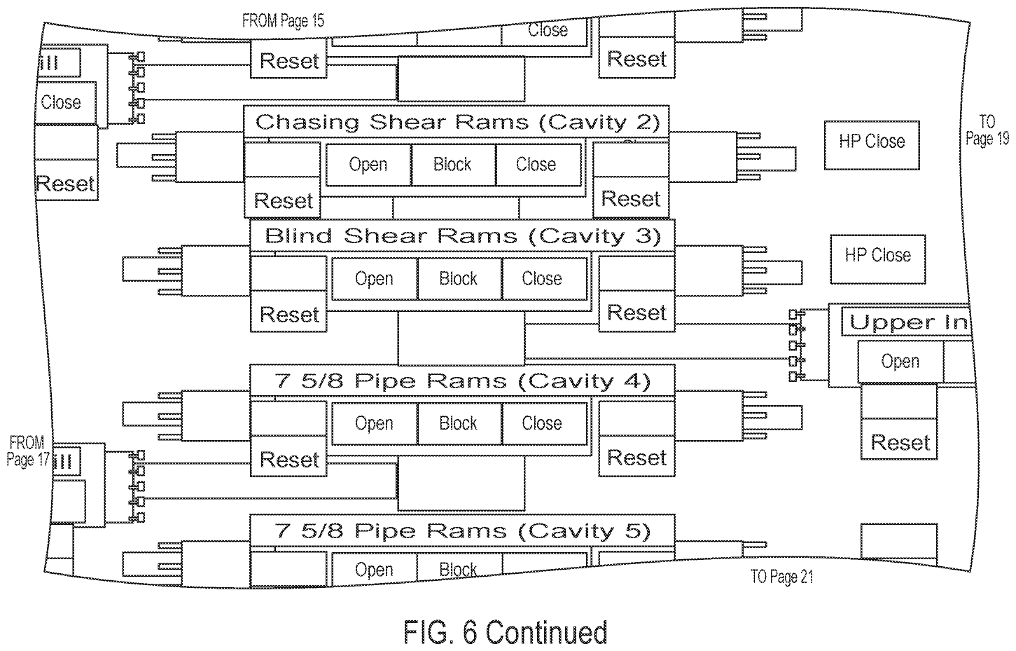

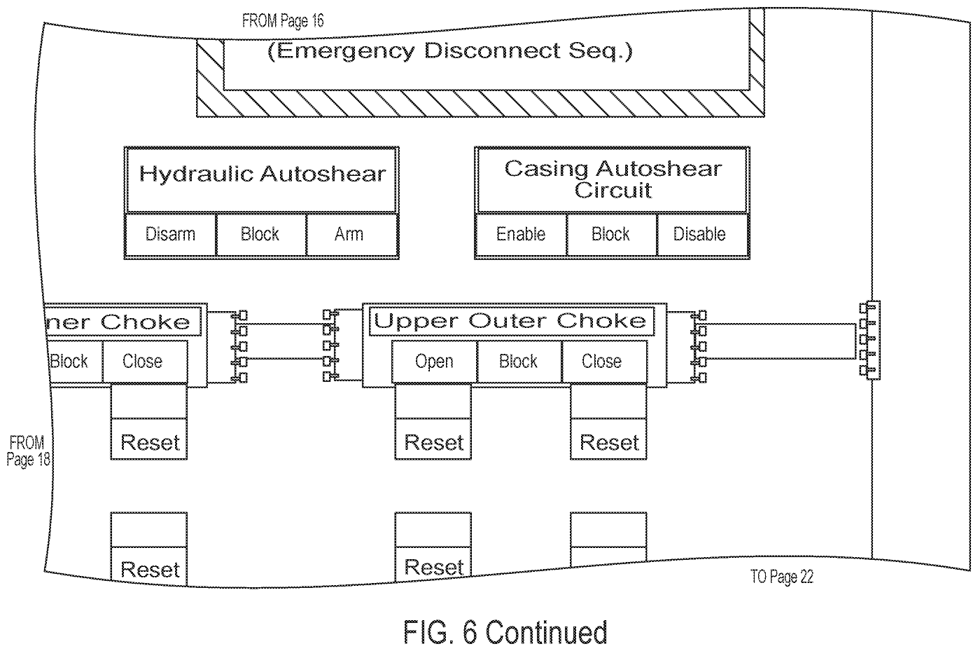

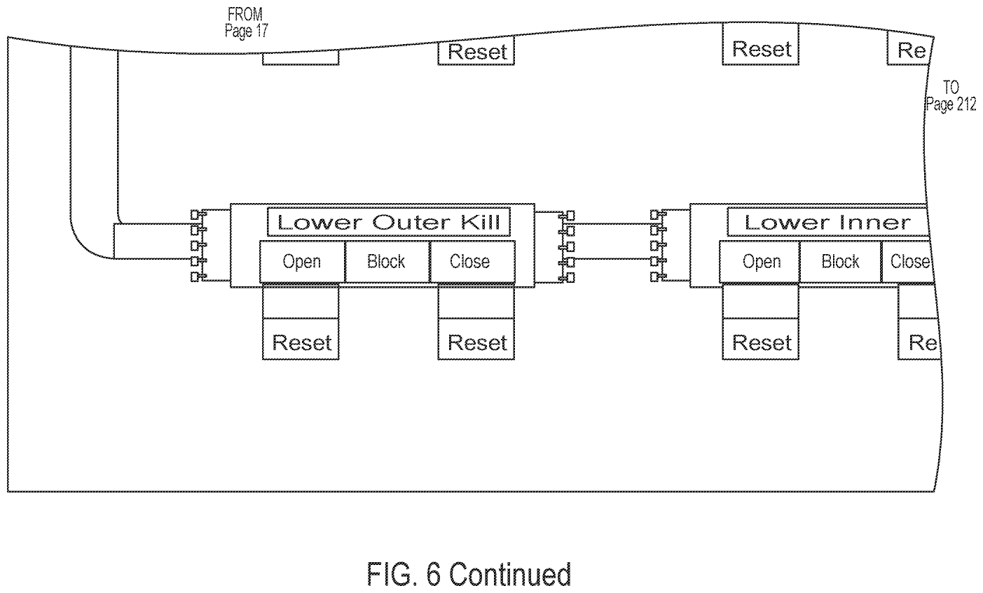

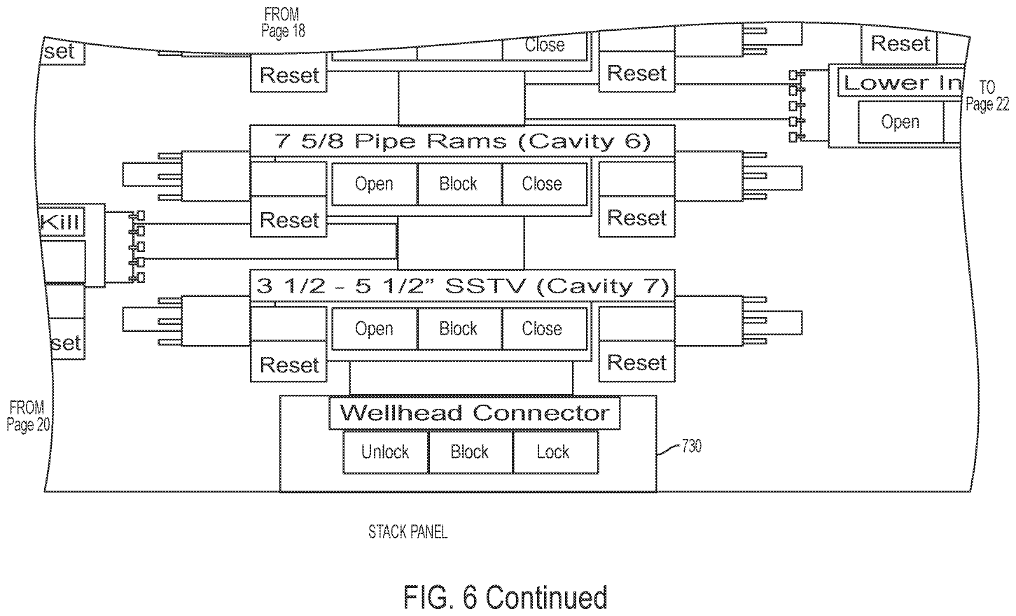

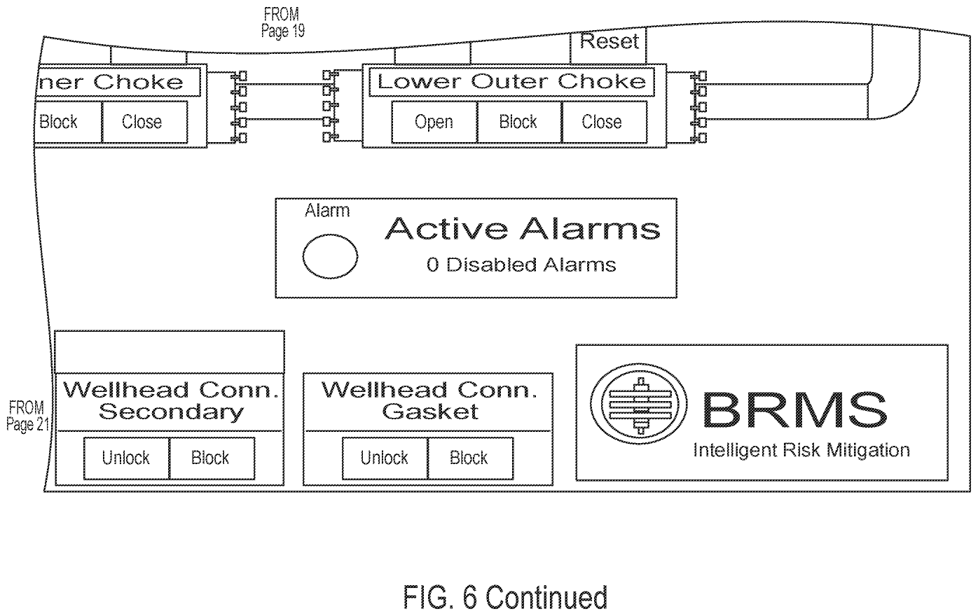

Referring now to FIG. 6, a Stack Panel UI 700 is shown according to an exemplary embodiment. The stack panel includes for example, wellbore components, choke and kill test valves, bleed valves, mud boost valve, pod select and Autoshear control. Similar to the UI 600, the UI 700 may reference a table of stored reactions for selected elements in the control system. In some embodiments, as will be appreciated, a change in state in one panel may affect a change in state shown in another panel and the changes may propagate through the various panels where a relationship (either direct or by downstream cause and effect) exists. Table 2 shows an identification of the basic groups of valves as they work similarly for the various components.

TABLE 2

| | | | Normal |
|---|---|---|---|
| | Unenergized | | Operating |
| Name | State | Information | State |
| Bleed Valves, | Solenoids & | These valves on the Outlets to the Stack all have a | Close |
| Choke & Kill | Directional | spring to close. So normal position with no | |
| Valves | Valves go | energization is close. All these valves are redundant | |
| | to vent | on each line. | |
| Choke and Kill | Solenoids & | The Choke and Kill Test Valves Button controls 2 | Open |
| Test Valves | Directional | valves; one on the choke line and one on the kill line. | |
| | Valves go | Those valves are fail-open. | |
| | to vent | | |
| Mud Boost | Solenoids & | The Mud Boost is a single Valve. It is also a fail-close | Open |
| Valves | Directional | valve. | |
| | Valves go | | |
| | to vent | | |
| Annulars | Solenoids & | These Items are directly on the wellbore and in | Open |
| | Directional | normal operation remain open. The annulars are a | |
| | Valves go | spherical BOP. | |
| | to vent | | |
| Rams, SSTV | Solenoids & | These Items are directly on the wellbore and in | Open |
| | Directional | normal operation remain open. These are RAM type | |
| | Valves go | BOPs with dual pistons. | |
| | to vent | | |
| Shear Rams | Solenoids & | These Items are directly on the wellbore and in | Open |
| | Directional | normal operation remain open. These are RAM type | |
| | Valves go | BOPs with dual pistons. The Shear Rams include the | |
| | to vent | ability to close with High Pressure. When Block is | |
| | | used after the HP Close, it will only indicate the lost | |
| | | position of close, not HP Close. | |
| Connectors | Vented | The Connectors are used to connect the stack to the | Lock |
| | | wellbore and the LMRP to the stack. These | |
| | | connectors have a standard Lock/Unlock function | |
| | | and additionally have a secondary Unlock. On the | |
| | | HMI, the secondary Unlock is NOT interconnected | |
| | | with the Lock/Unlock buttons and care should be | |
| | | used to ensure that the secondary Unlock is in the | |
| | | BLOCK position prior to trying to LOCK the primary. | |
| Connector | Solenoids & | The gasket seals between the connector and the | Retract |
| Gaskets | Directional | mandrel It is held in place with small pins | |
| | Valves go | hydraulically inserted. The release is to retract these | |
| | to vent | pins. | |
| Connector | Solenoids & | The connector flush circuit allows a path to flush | Open |
| Flush | Directional | hydrates from the connector as needed. | |
| | Valves go | | |
| | to vent | | |
| Pod Select | N/A | This valve will select a pod to be operational. The | N/A |
| | | system is designed that the solenoids in both pods | |
| | | have fluid on them always. Additionally, the system | |
| | | is designed where the lower portion of the pods, the | |
| | | directional valves and regulators only have fluid on | |
| | | ONE pod at a time. By selecting a pod, there is a | |
| | | valve activated in the selected pod to allow 3000 psi | |
| | | fluid to the lower pod directional valves. The pod | |
| | | select also operates a valve in the Conduit package | |
| | | via line 51 to allow 5000 PSI fluid to the lower | |
| | | selected pod for High Pressure functions. | |

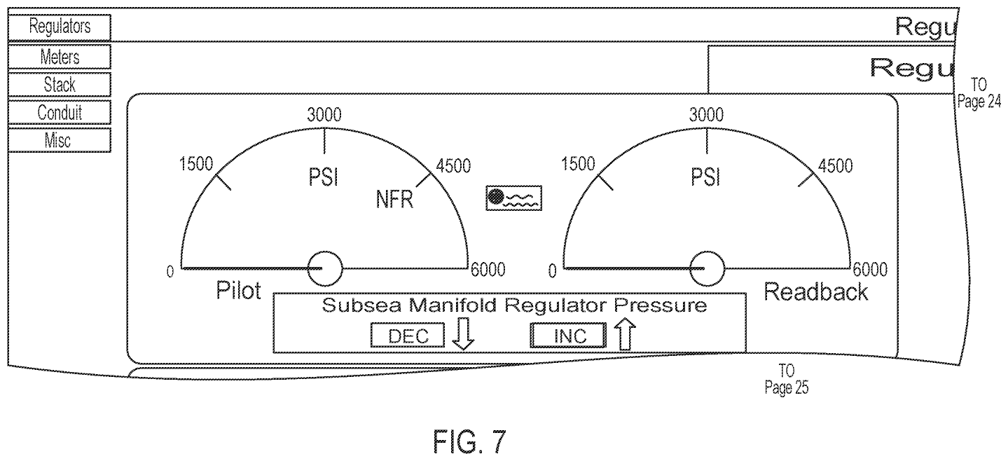

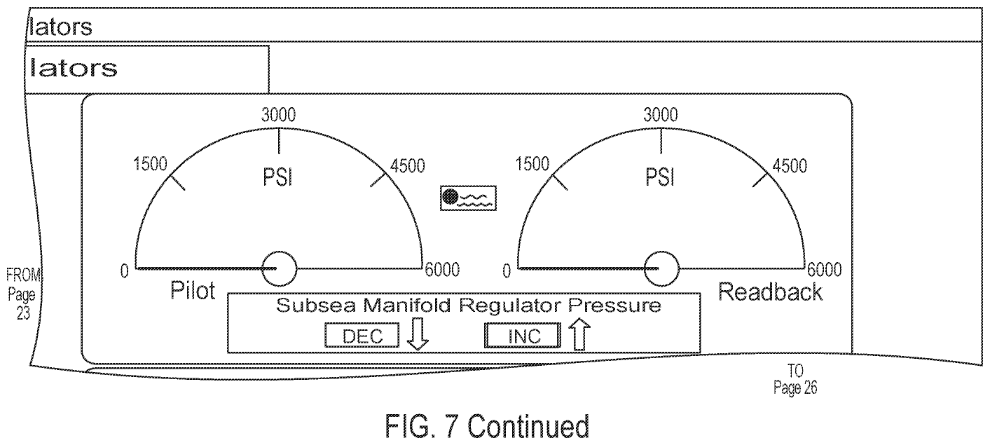

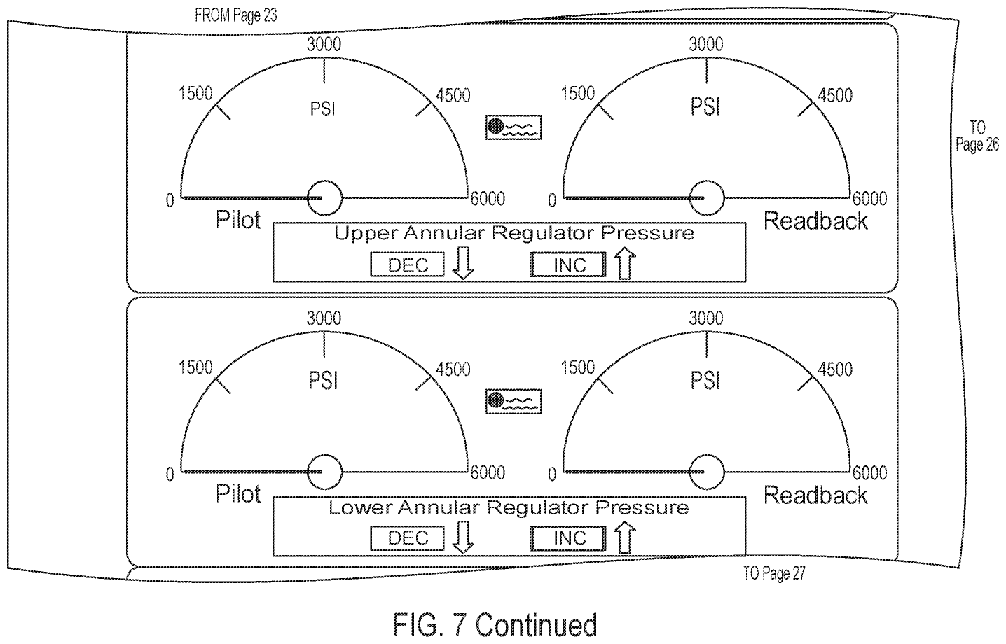

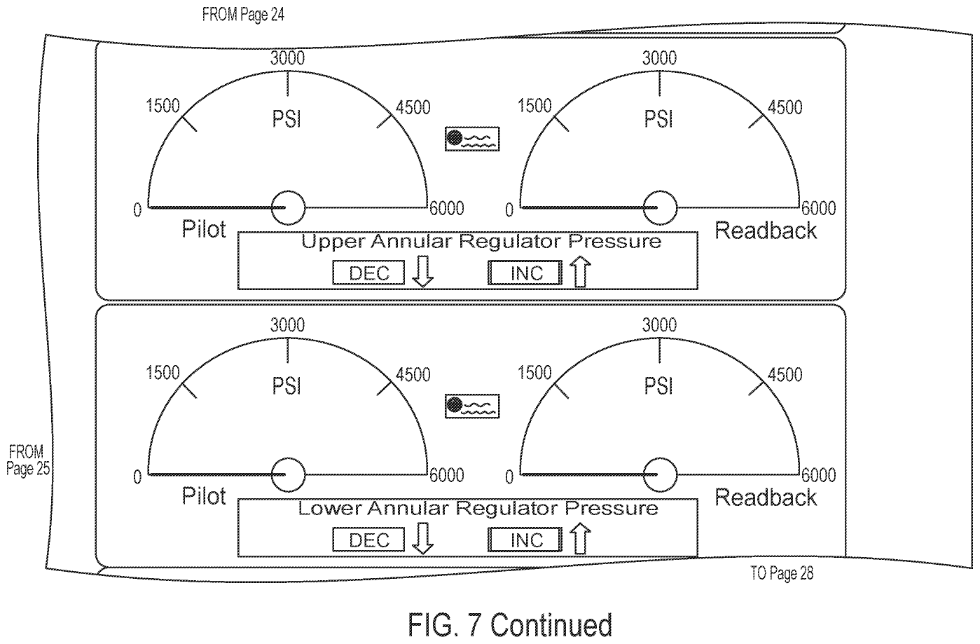

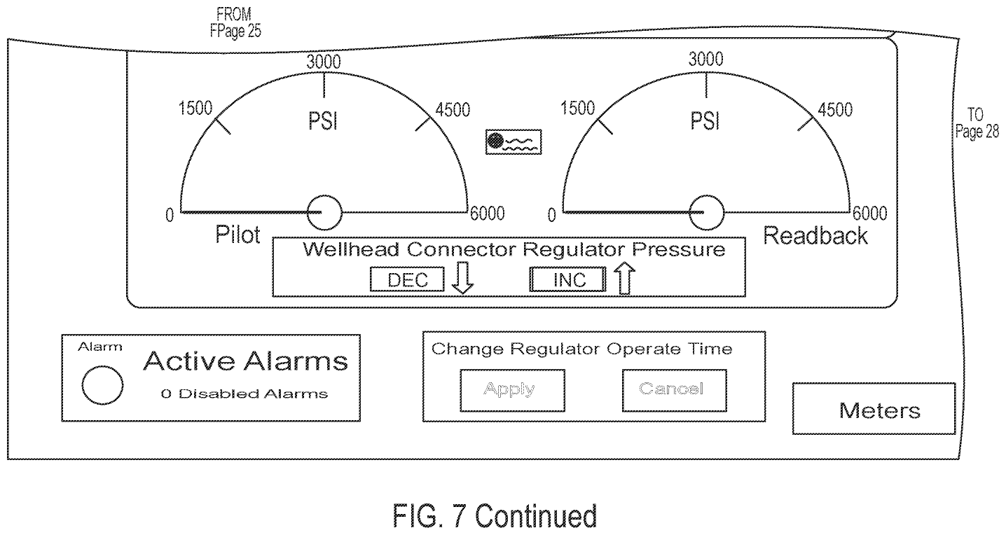

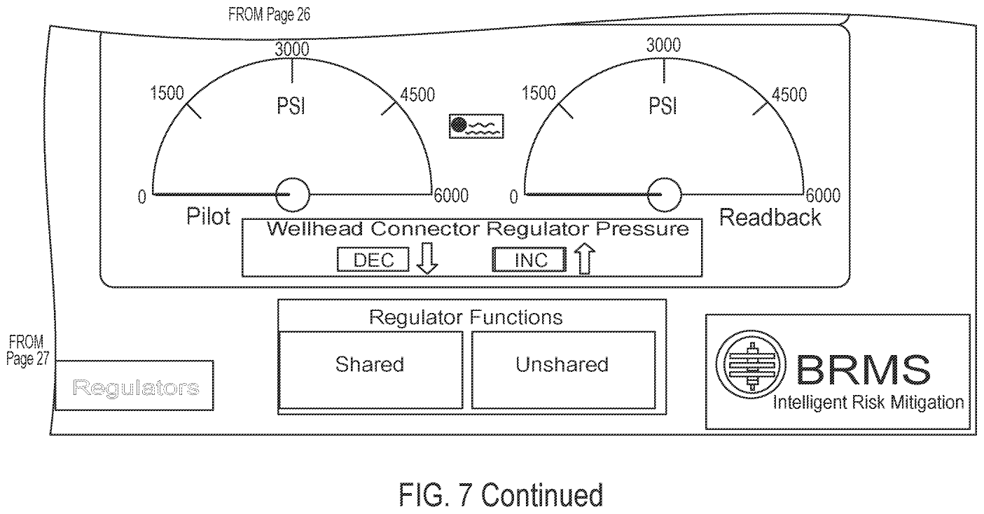

Referring now to FIG. 7 (concurrently with reference to elements shown in FIG. 6), a regulator panel 800 includes control and readouts of the four regulators in each pod, which are the Manifold Regulator, the Upper Annular Regulator, the Lower Annular Regulator and the Wellhead Connector Regulator. These are for the main Manifold supplying the pod valves, the Upper 710 and Lower Annulars 720 separately and the Wellhead Connector 730. The gages indicate the readback from both pilot and downstream of the regulator. In some embodiments, these may be designed for a 1:1 ratio, therefore if the user desires 1500 PSI downstream, the Pilot should be set to 1500. It may be typical to see fluctuation in the pressures on these regulators as components in the system are shifted and fluid is flowing.

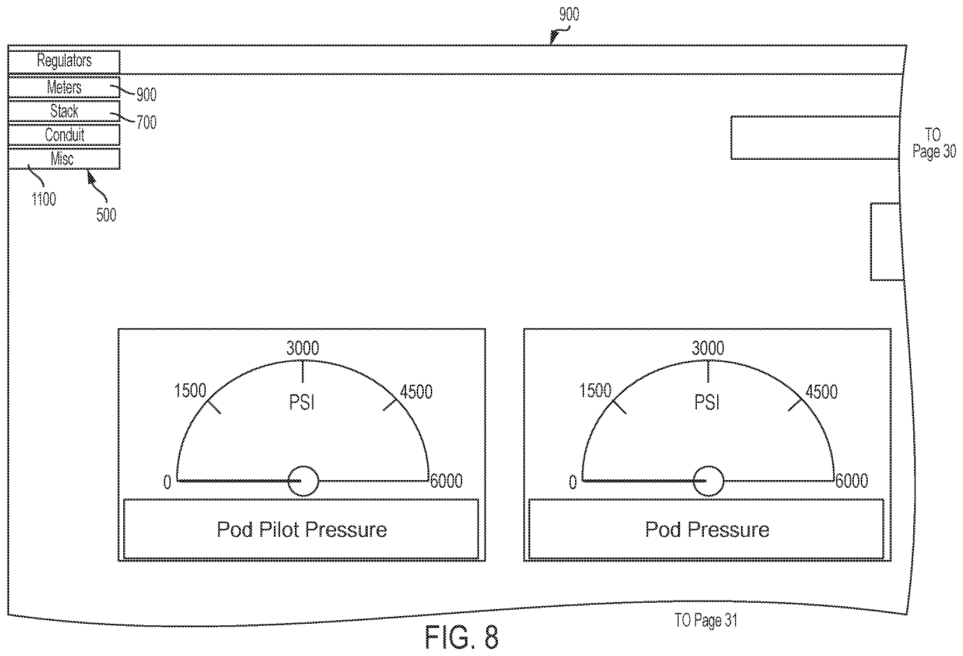

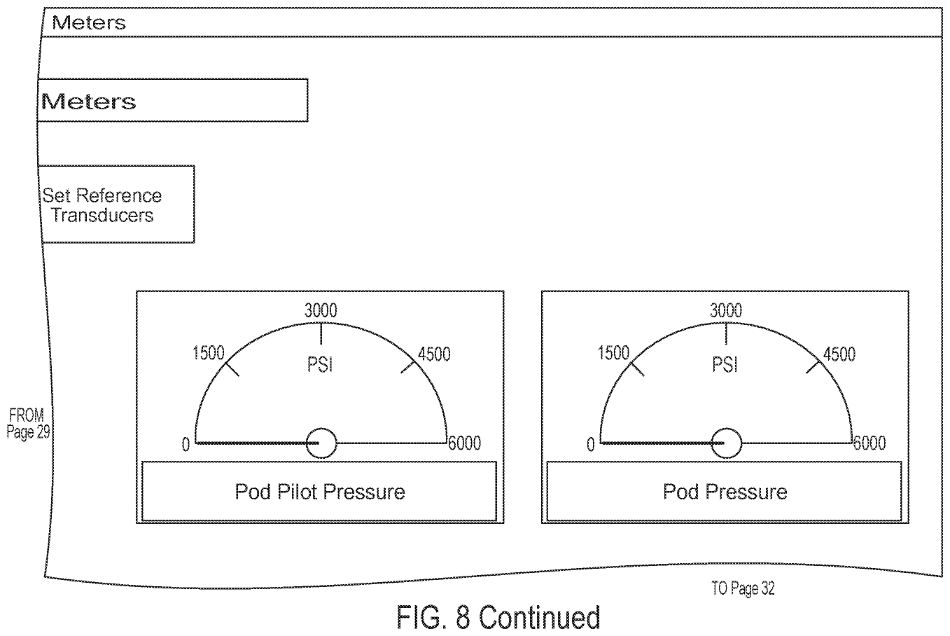

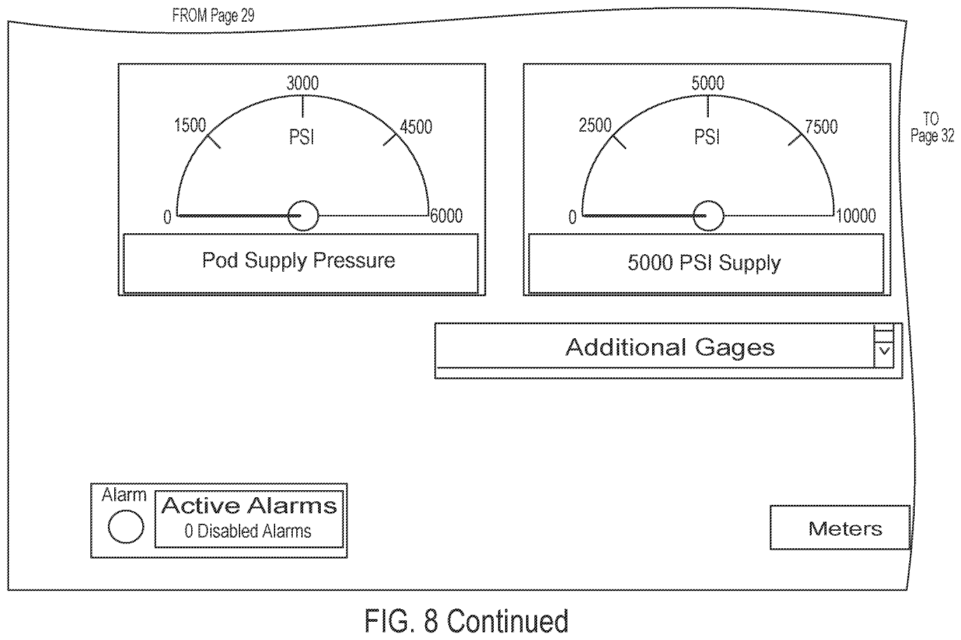

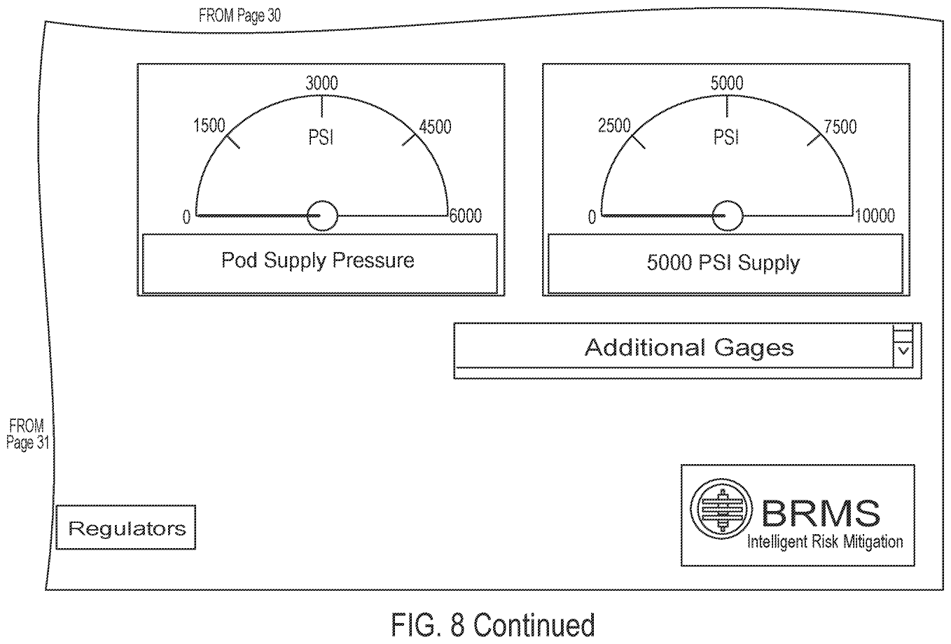

Referring now to FIG. 8, a meters UI 900 is shown according to an exemplary embodiment. The meters UI panel 900 contains gages to monitor other pressure transducers in the system. These include the Pod Pressure, the Pilot Pressure, the Pod Supply Pressure and the 5000 psi Supply gage. Below this last gage is a button that will take you to the additional gages in the system. The drop-down menu includes pressure gages for the following gages that do not show up elsewhere in the UI system.

Wellhead Connector Primary Unlock Readback

Wellhead Connector Secondary Unlock Readback

Wellhead Connector Lock Pressure Readback

LMRP Disconnect Pressure

Riser Connector Unlock Pressure Readback

Riser Connector Lock Pressure Readback

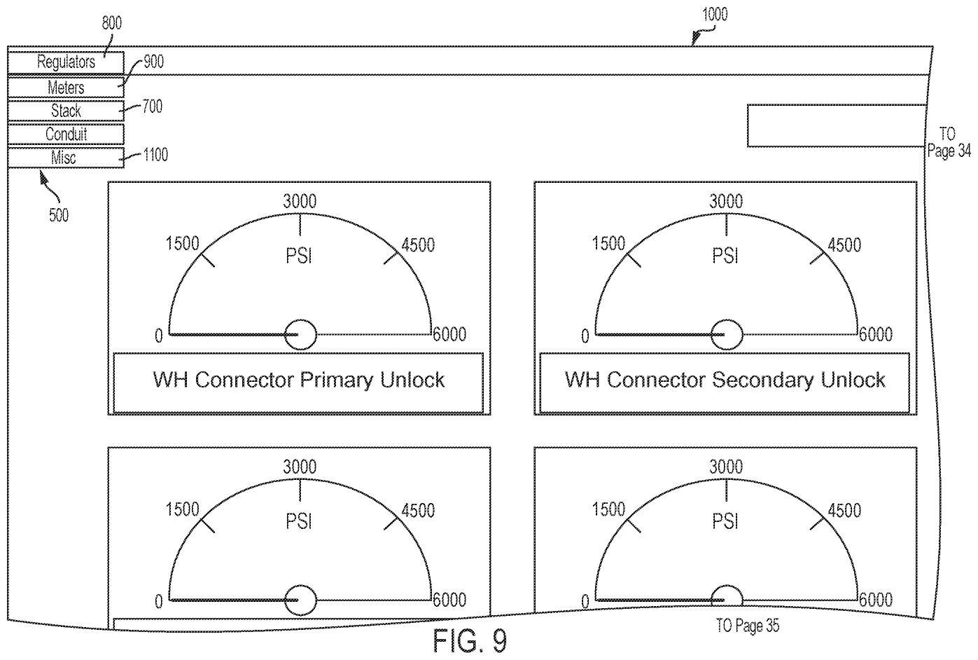

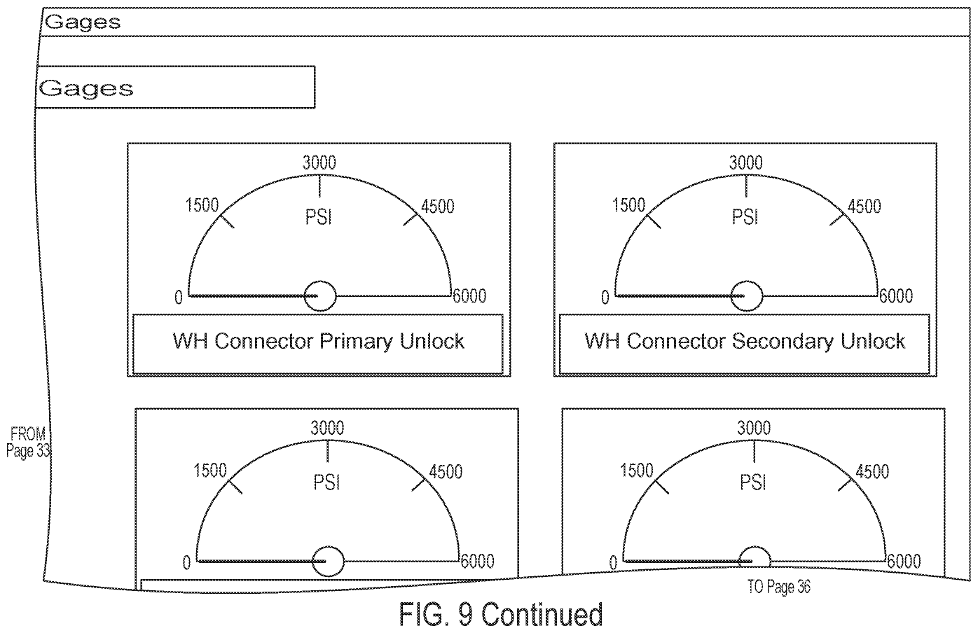

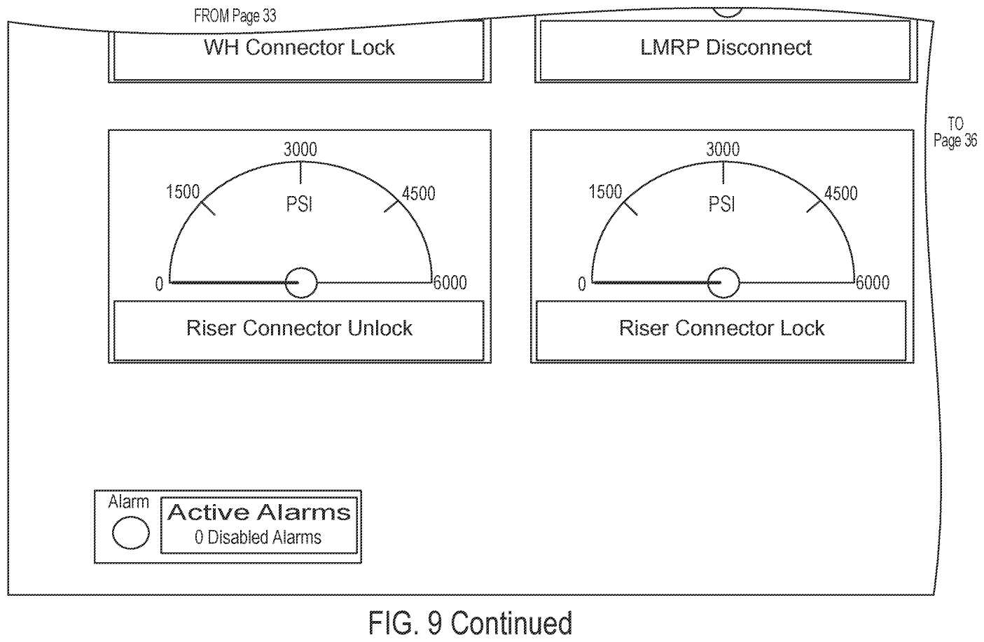

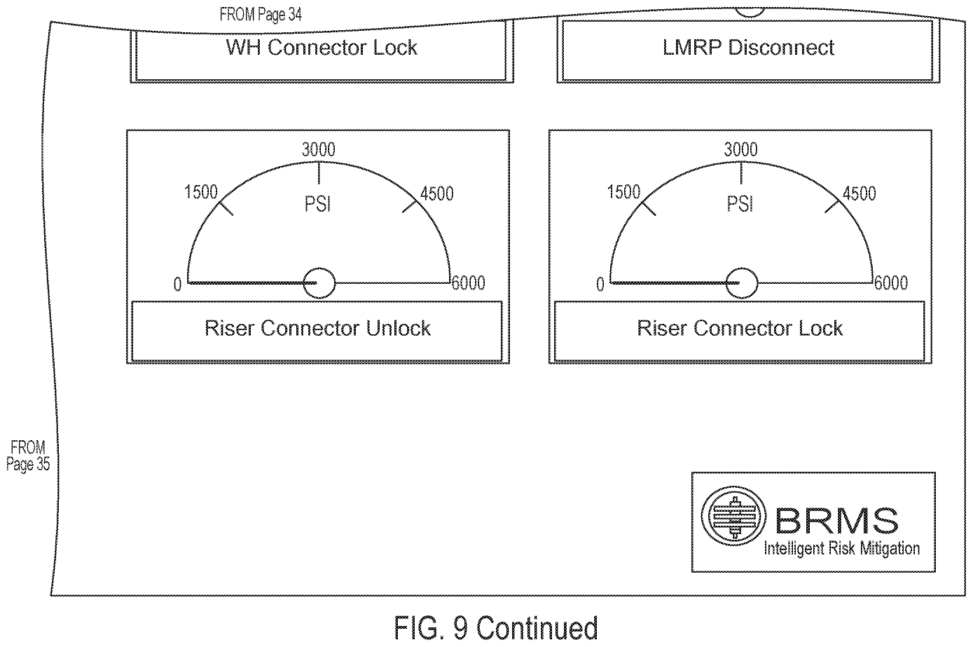

Referring now to FIG. 9, Additional Gage Panel UI 1000 is shown according to an exemplary embodiment. This panel may be accessible from the Meters Panel via the “Additional Gages” button. On the vessel, the meters panel has a drop-down menu to access these (and all other) gages. In the Smart-Sim the link below the 5000 PSI Supply Gage will take you to this page.

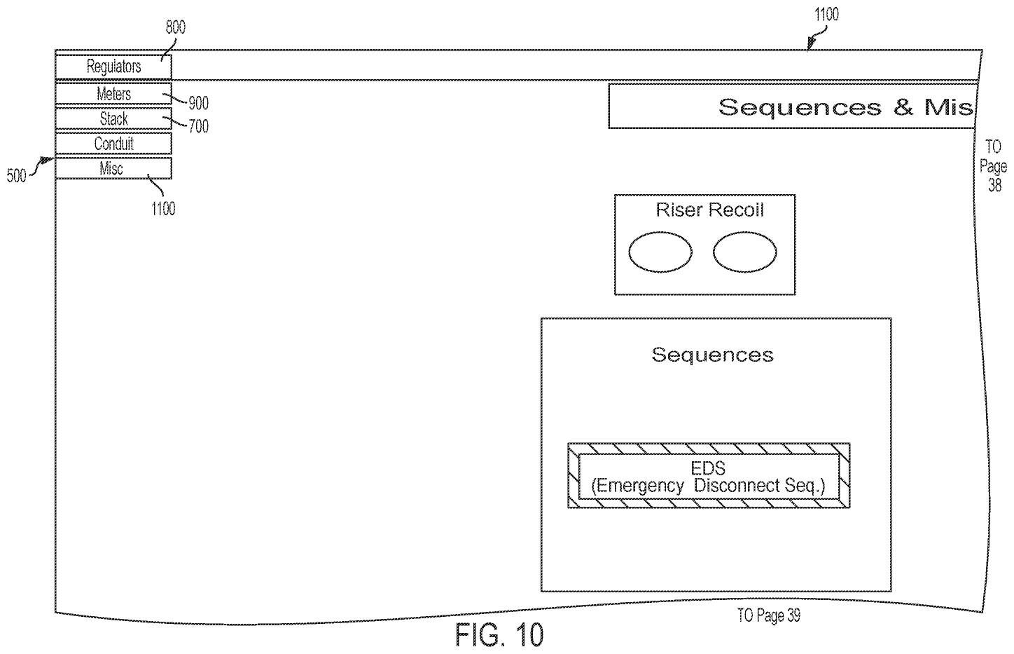

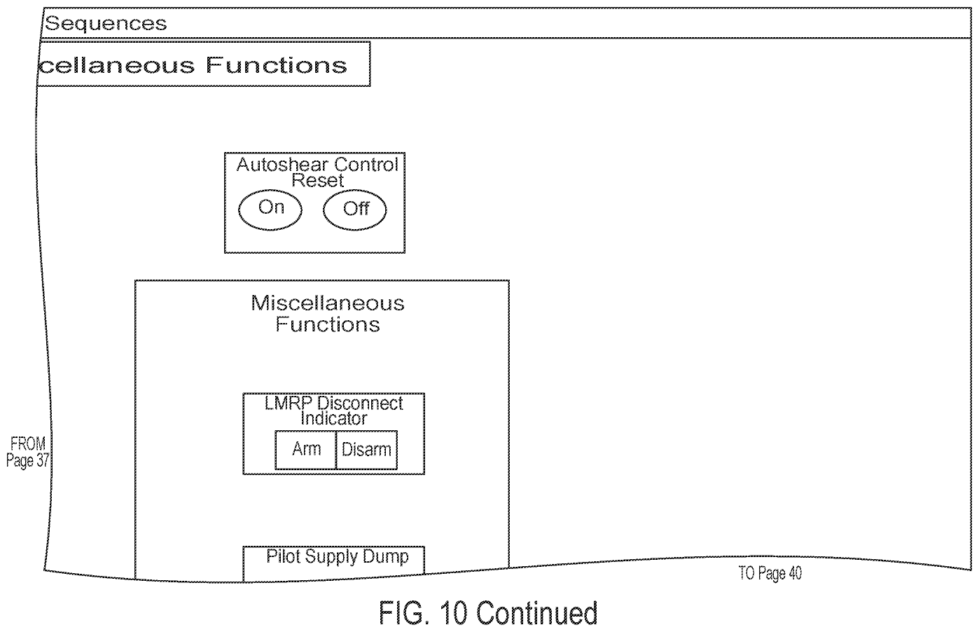

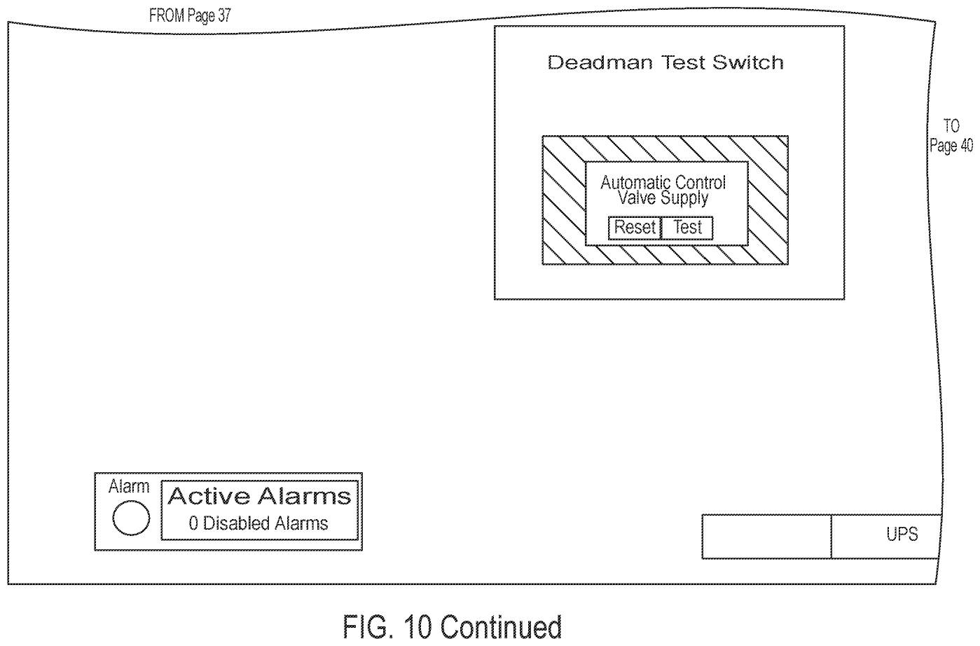

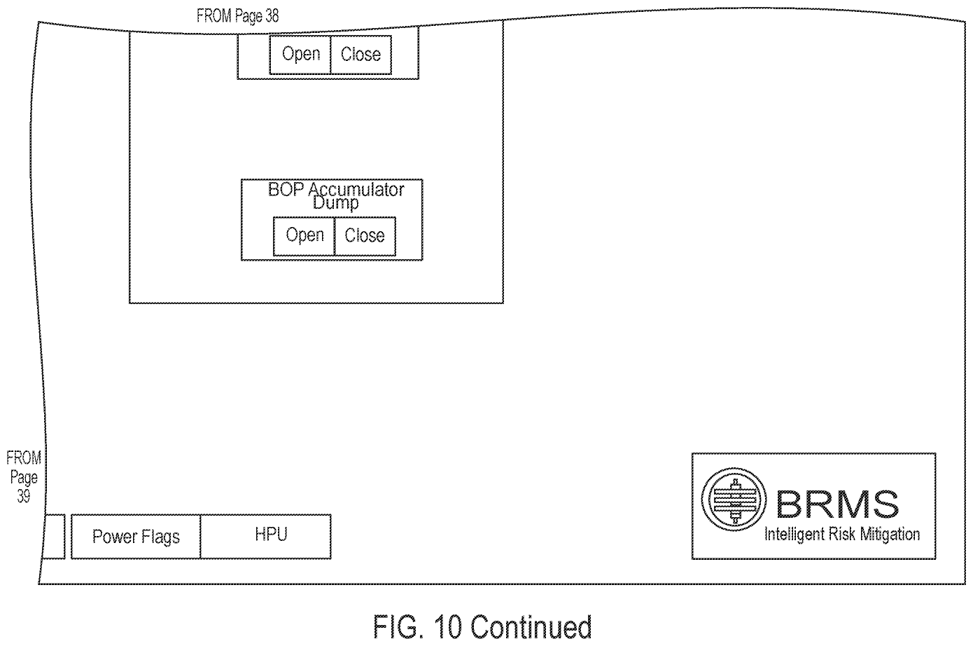

Referring now to FIG. 10, a miscellaneous panel UI 1100 is shown according to an exemplary embodiment. In the exemplary embodiment shown, the only active button on it is the Autoshear Control Reset. The other buttons are included in the stack panel 700 and the auxiliary panel 600 and can be accessed on those panels.

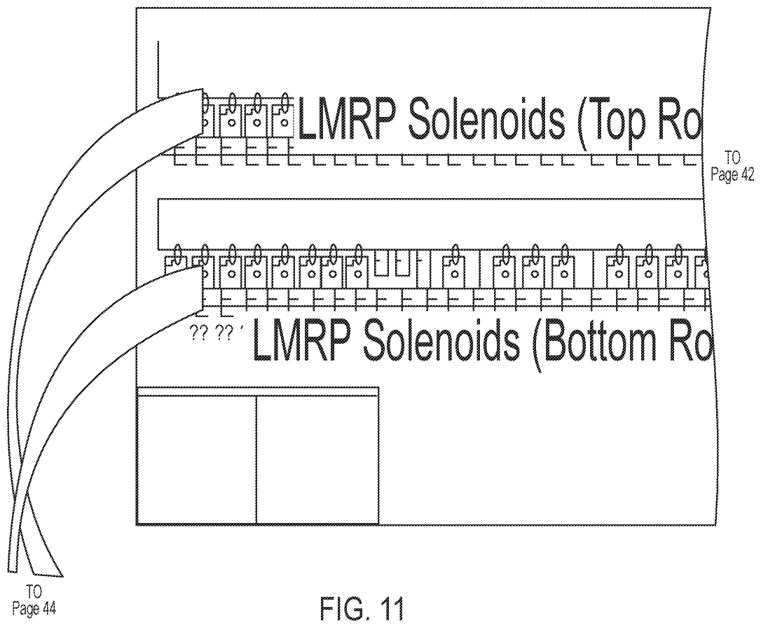

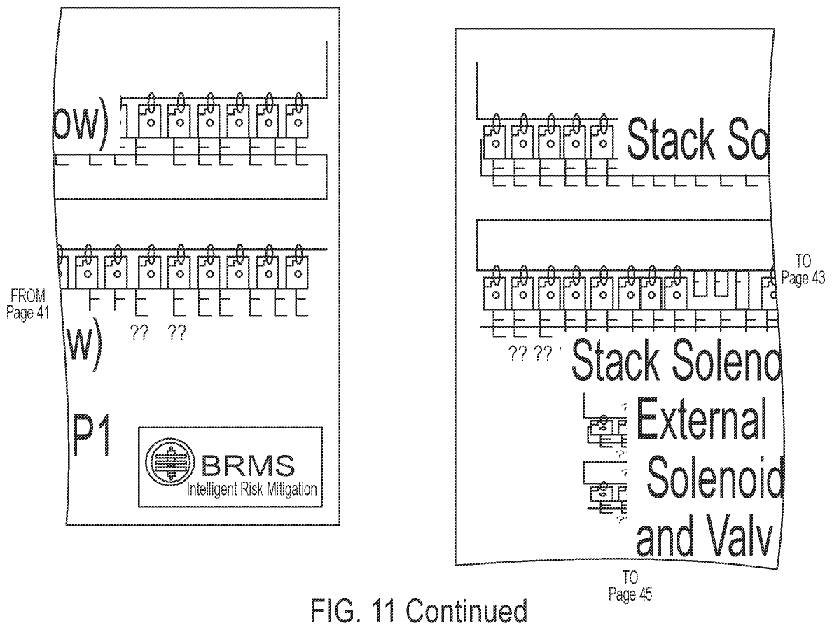

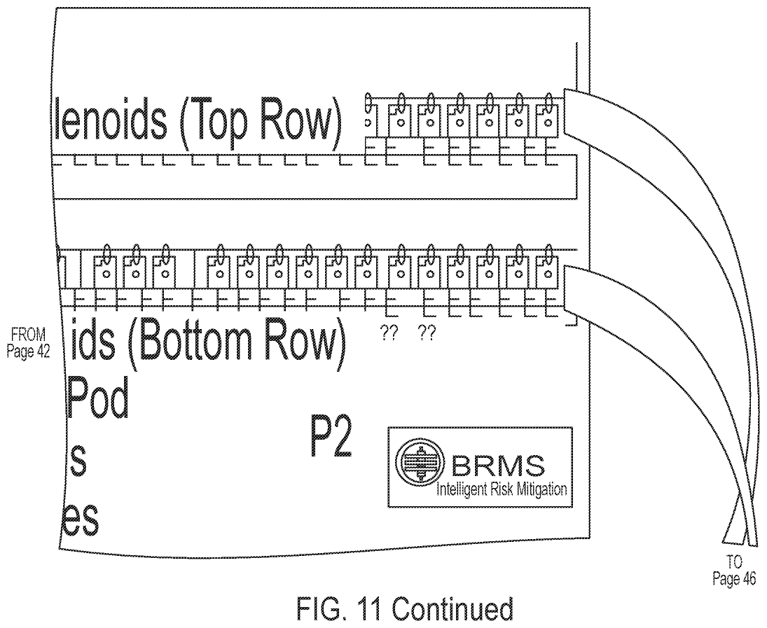

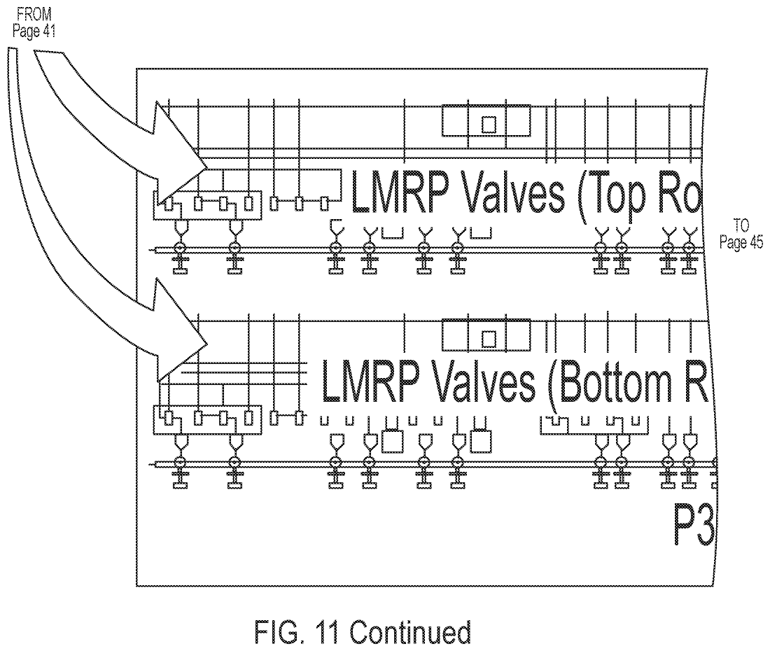

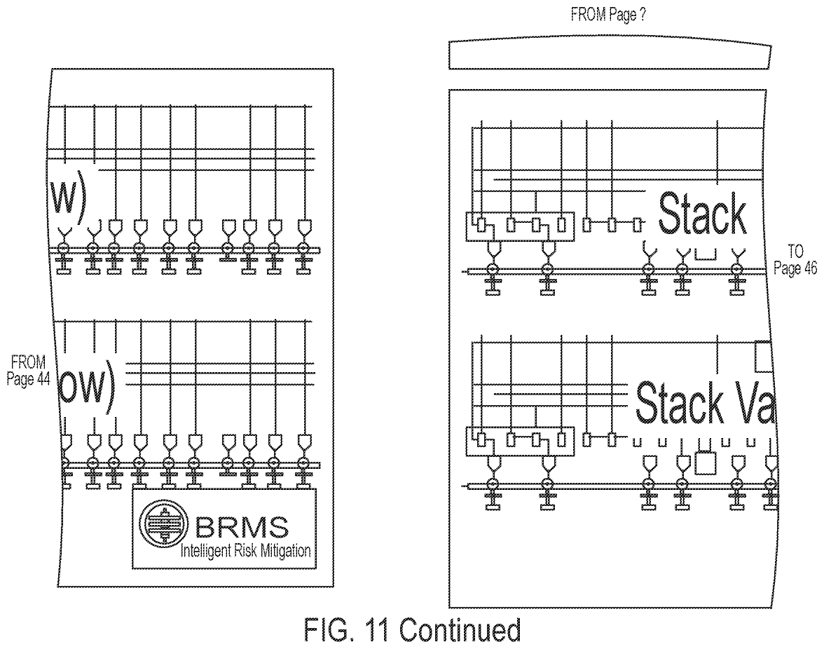

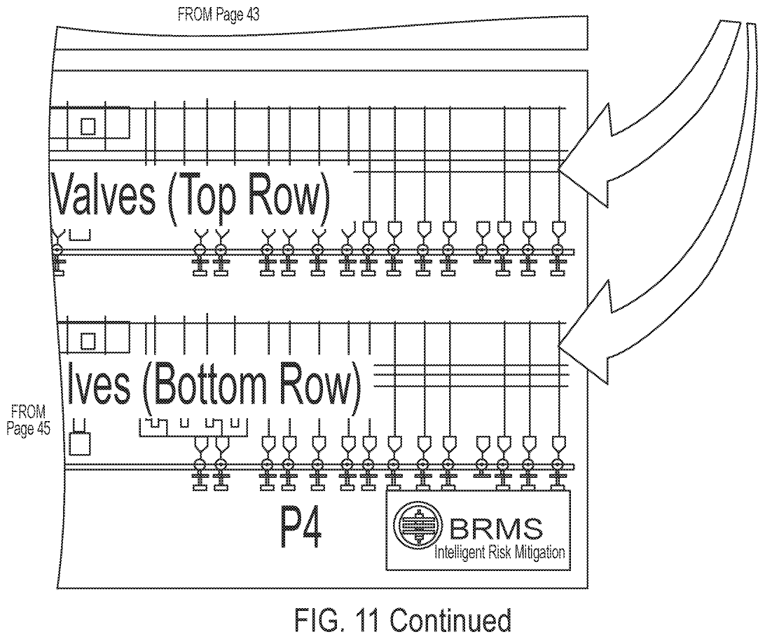

Referring now to FIG. 11, a schematic showing the relationship between control pods in the control system is shown according to an exemplary embodiment. As discussed above, each control pod module may not be seen simultaneously on embodiments of the UI system. When an element in one control pod is activated for its effect on the control system, a resultant effect may often be offscreen and shown in a separate UI module. The user, through means such as the jump links described above, may move around the control system instantly to see effects all around the system.

In the exemplary embodiment shown, the two control pods are identical. The schematics are set up in the following logic: The solenoids appear on the first two pages and the directional valves appear on the next two pages. The LMRP functions are on P1 and P3; the Stack functions are on P2 and P4. The break in the lines on P1 corresponds to the same break on P3 and similarly between P2 and P4. The exception to this layout is the functions in the external pod, which are at the bottom of sheet P2 on each pod. This external pod includes both the solenoids and directional valves. The external pod contains the functions for the Inner and Outer Lower Kill Valves. The relationship between elements is depicted by the arrows originating from a row of elements in one pod and terminating in a row of elements in a connected pod. As can be seen, for example, LMRP solenoids in the top row of P1 affect LMRP valves in the top row of P3. Other relationships can be gleaned from the arrows depicted.

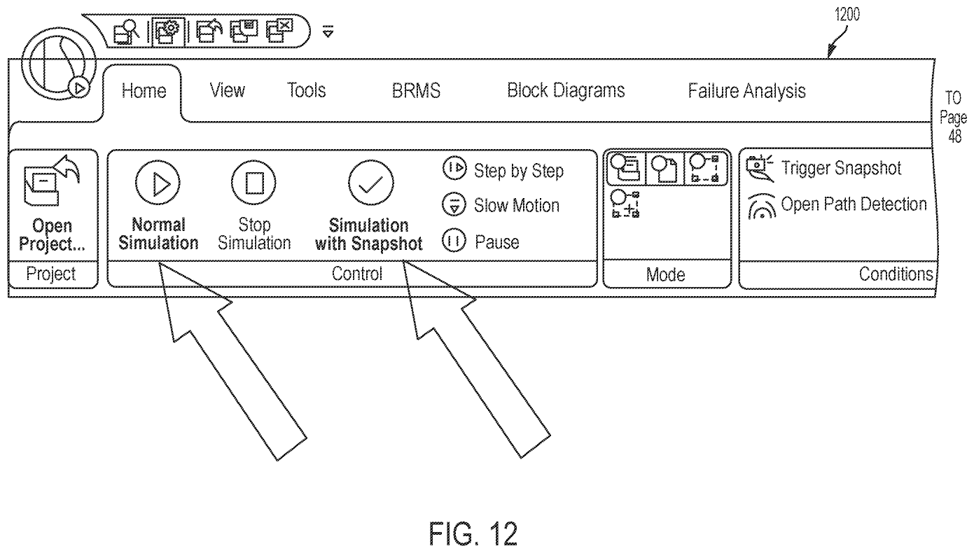

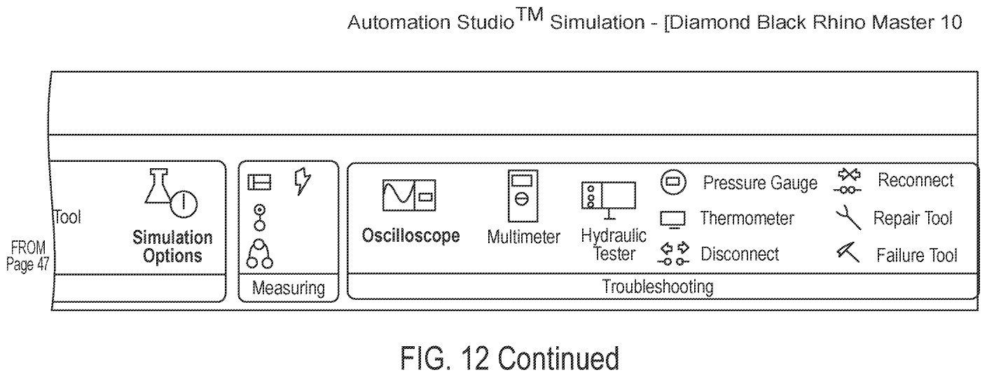

Referring now to FIG. 12, to start Simulation Mode, a user may Select from UI 1200, the Home Tab from the top of the screen. Simulation can be initialized in either the normal mode or from a “snapshot”. The simulation system is delivered with a snapshot to start simulation. The snapshot has the system set in normal operating mode with:

all the wellbore components open;

the side outlet valves closed;

the regulators set to:

WH—750 PSI

LA—1500 PSI

UA—1500 PSI

Manifold—1500 PSI

Manual in Conduit Package—3000 PSI;

the subsea accumulators charged to a precharge at 1200 PSI;

both Conduits selected; and

Yellow Pod is selected.

This is provided to allow a quicker start up than the normal process.

Normal Simulation

The normal simulation process begins with all valves in their inactivated state except for the “Autoshear Control Valve Supply” (Solenoid #15). That solenoid is activated at initialization, as it is wired on the vessel to be activated always. The background of the UI panels will be in a gray state until a pod selection is made. All buttons will be in a gray state until a selection is made.

It is recommended that initial set up be completed following normal rig training. Once a pod is selected, the background color of the UI panels will change color to blue or yellow corresponding to the pod selected. The simulator will take time to start up from a normal position. This is caused by the simulator filling accumulator bottles, lines, etc. Allow the regulator gages to become steady and the flow meters to stop before assuming the system is stable.

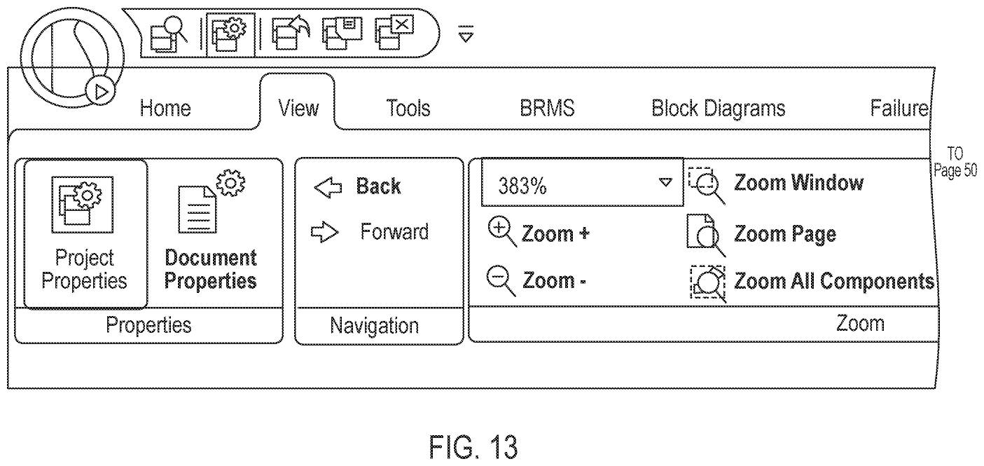

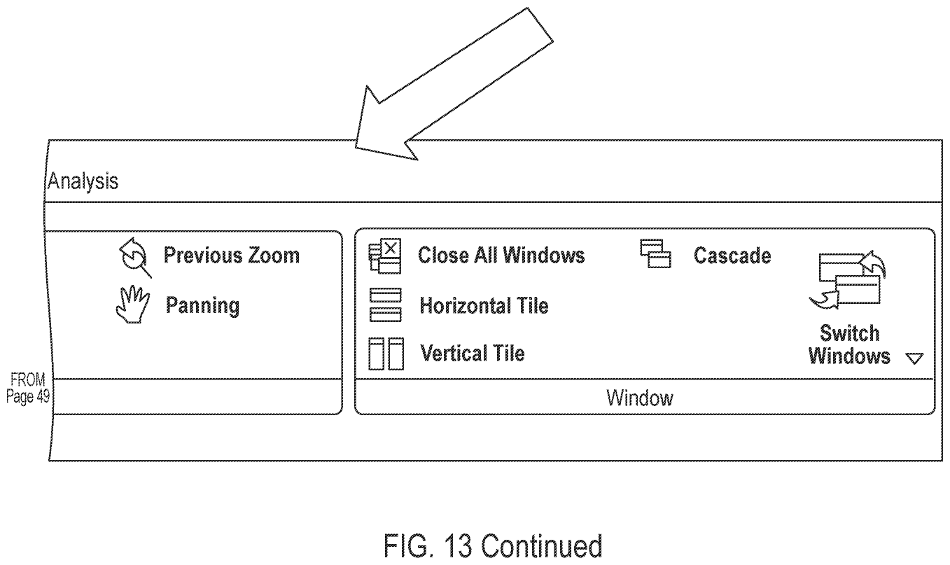

Referring now to FIG. 13, during simulation, more than one module window can be open. This may be desired when the user is wanting to see the valves or the rams move while still having a UI panel active and available. Under the “View” tab, to open a second module, the user can minimize the first window and select a second or third document from the banner. Additionally, if it is desired to have all documents open, there are options on the View tab to organize the documents in different arrays. There are numerous ways to interact with the simulator. All solenoid controlled functions are activated from the UI panels by using your mouse over a button. Valves that have a hydraulic pilot will be shifted in accordance with the hydraulic pressure applied to the pilot.

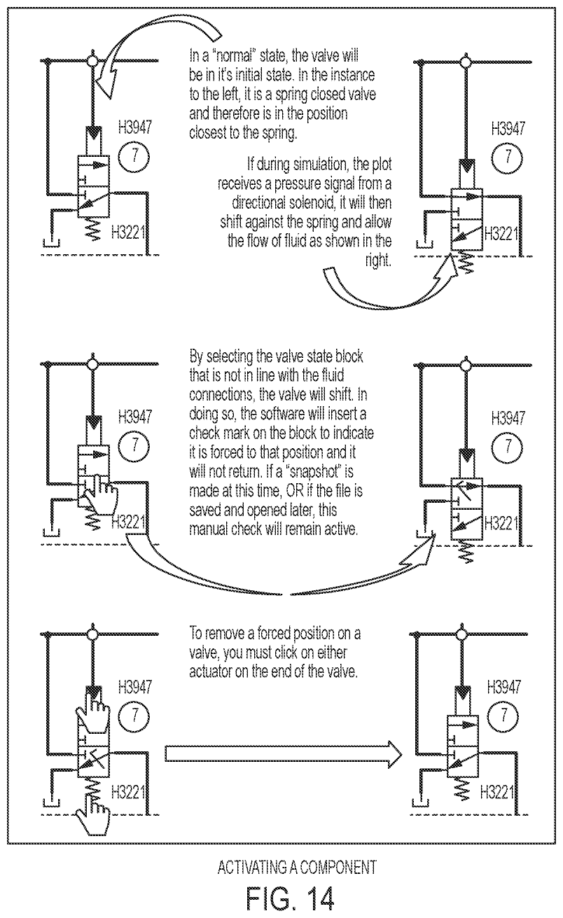

Examples showing what a user sees in a UI by clicking on an element, for example, a valve is shown in FIG. 14. The manually controlled valves, which are mostly ROV controlled valves are activated by clicking on the graphic of the valve itself. By clicking on the actual spool diagram or “valve state block”, the user can manually shift the valve. To release a manually shifted block, the actuator on either end of the valve must be selected.

In addition, the UIs are configured with features that show how the user can simulate failure modes. This feature allows for the user to show the effects in the system of a failure in one or more components. This can also lead to ensuring that a single failure does NOT affect the system capabilities. To simulate a failure, the user may access the home tab in UI 1200 (FIG. 12). Once a simulation is started, additional tools on the home tab will become available. These tools have the ability to instill a failure and then to repair the failure. All of these tools have additional help and explanation within the system. To access, the user clicks on a tool and then clicks on the help icon. An additional pop up window will open with further explanation and support.

Failure Analysis

The purpose of the Failure Analysis tab (FIG. 12), is to assist in marking items within either the BRMS Master Simulator or the Block Diagrams of the Family of Functions to indicate a Failed Component.

Highlight Tools

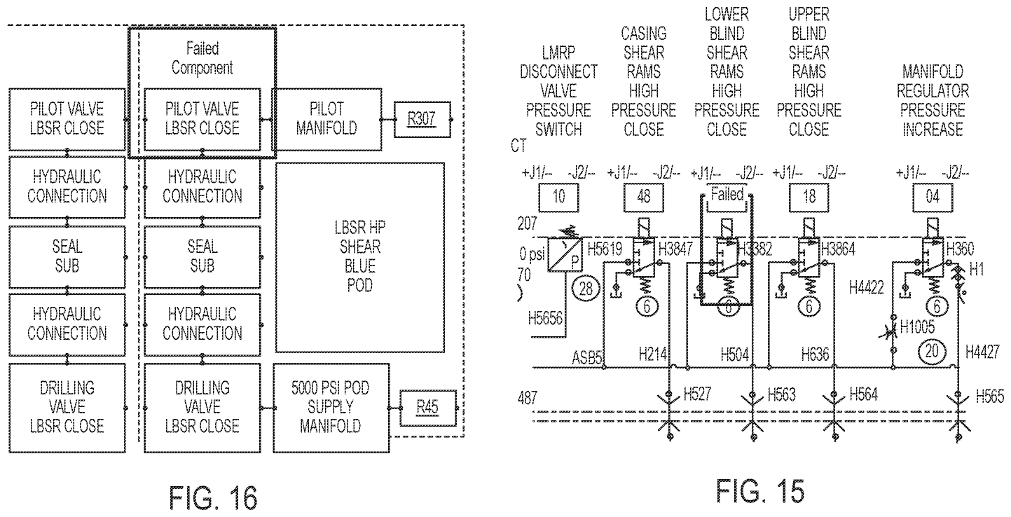

Referring now to FIGS. 15 and 16, there are several Highlight tools to be used to indicate specific conditions. These tools are to assist in communication. A user may click on a component in the Master simulator or a box in the Family of Functions Block Diagrams, then select the highlight wanted. The system will insert a box around the component to identify its condition. Screen shots can be taken and the saved information can be used in reports or memos to fully identify to others the condition. FIGS. 15 and 16 show the highlight tool identifying failed components in the system.

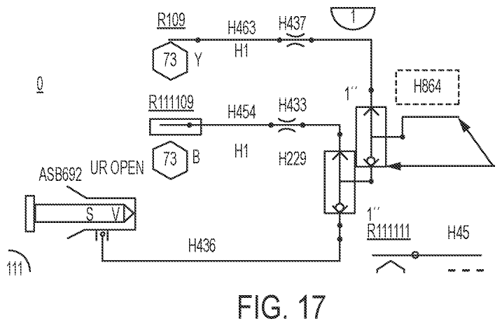

Within the Master File and accessible from each UI panel is a Risk Report Button. This link will access the report form to be used when required. Clicking on the Risk Report button brings up a new window (which may be shown as a spreadsheet for example). Each component and line within the Master Simulation File has a unique identifier number; the Component ID Number, associated with it. Most individual components begin with an HXXX and Assembled items begin with ASBXXX. These numbers are used in the FMECA database report. If a component has a failure, the unique identifying number in the Component ID field of the Report may be entered. Once the Component ID is entered, it may take a few seconds, but the Component Failure Mode drop down menu will be populated with options for that component. Selecting the failure will autogenerate the report. FIG. 17 shows an example of a component with associated identification that if selected, provides the menu option for triggering the autogenerated report.

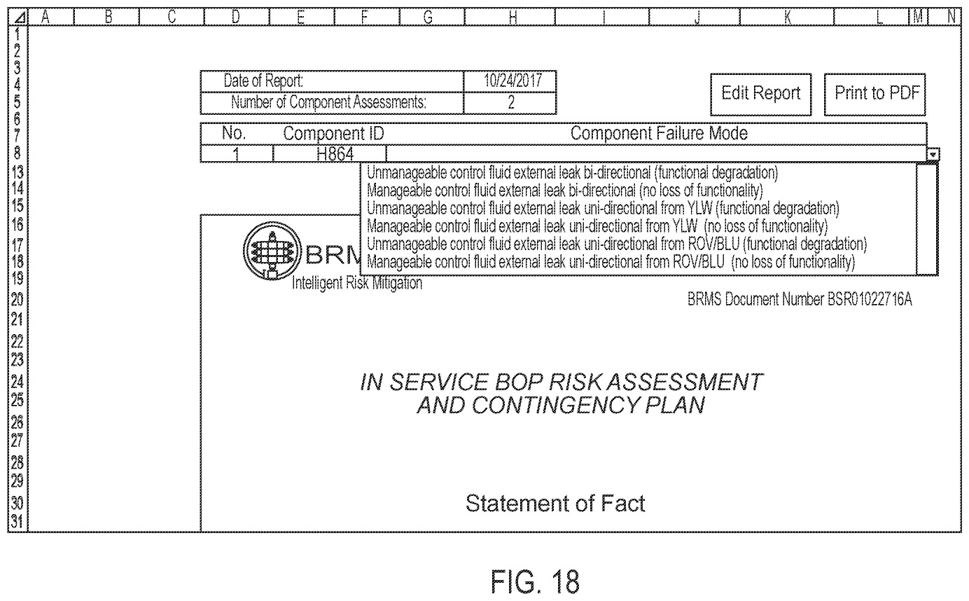

Referring to FIG. 18, a report generated by the system displaying a risk assessment and contingency plan is shown.

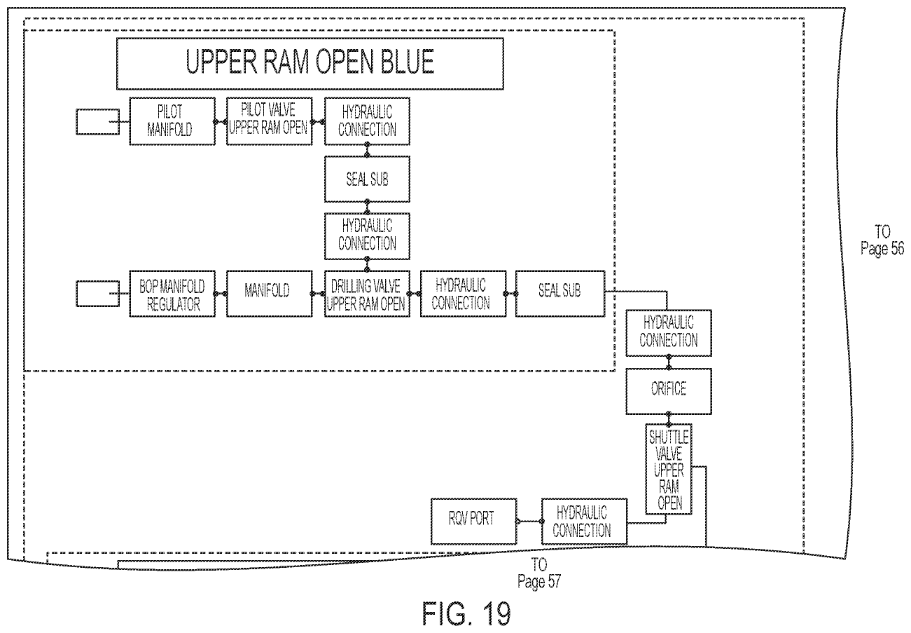

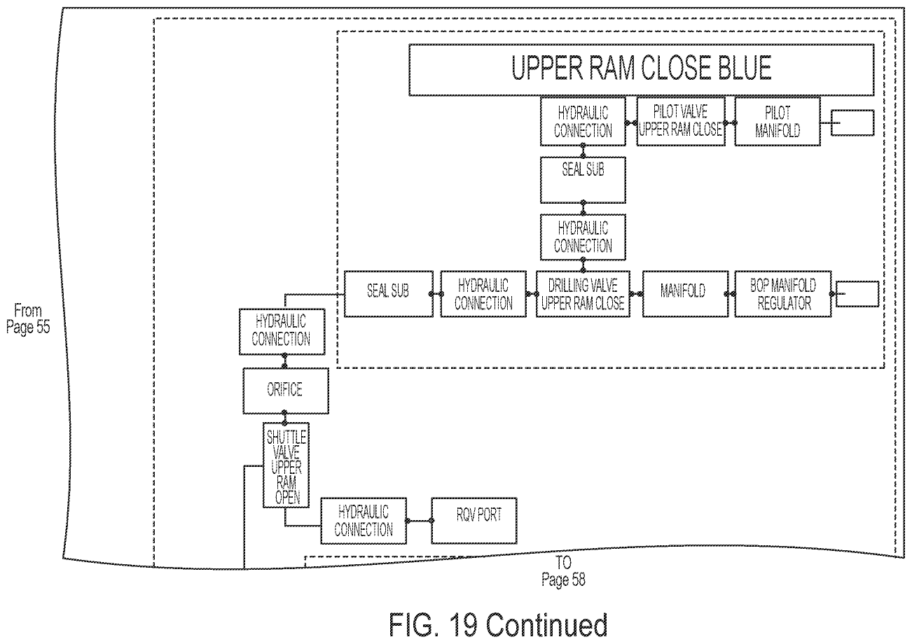

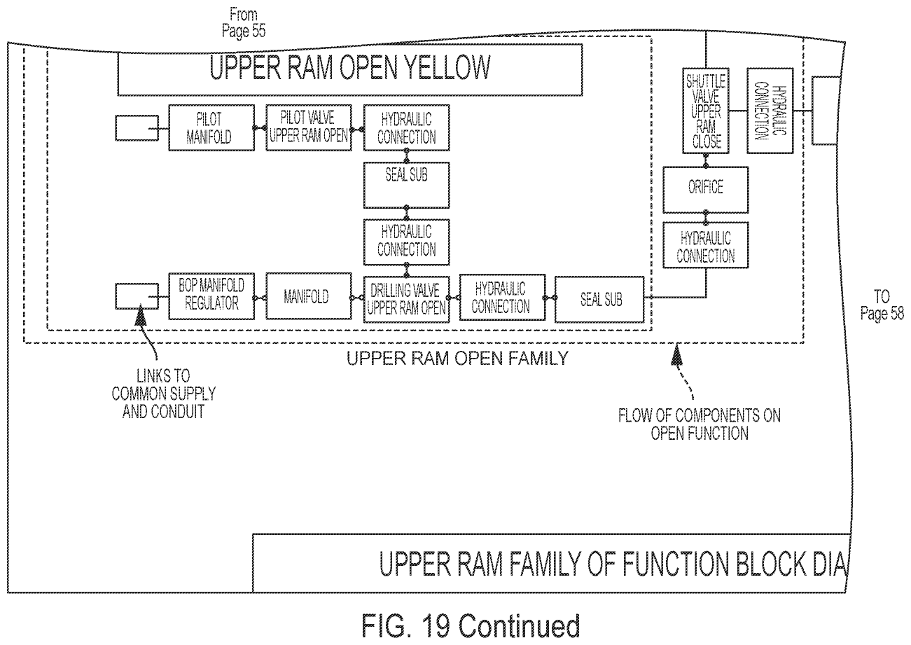

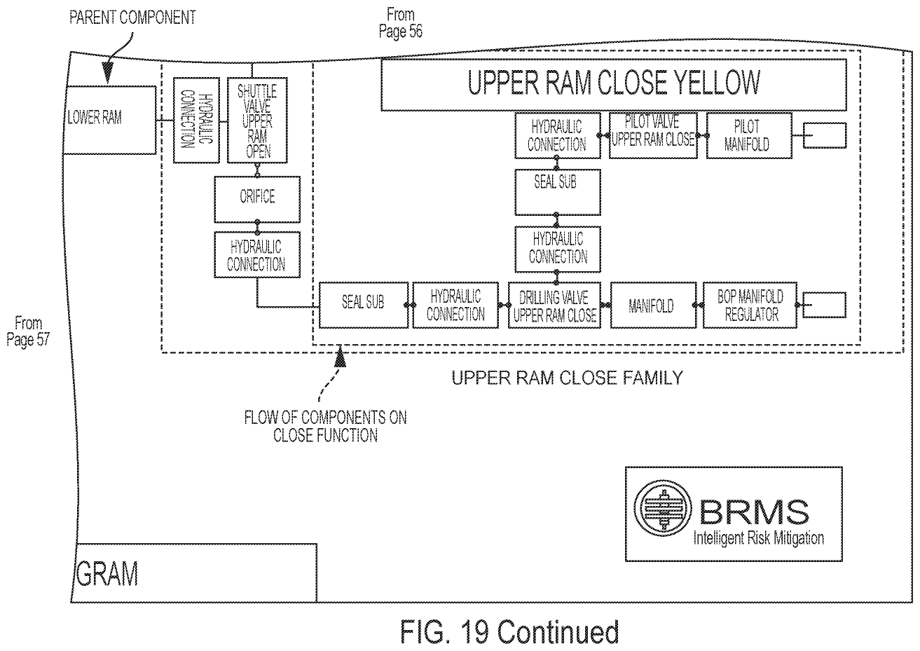

Referring now to FIG. 19, a block diagram of the control system is shown. As discussed above, the control system under evaluation may be highly complex and large. Some embodiments store a file that maps the connection relationship between elements. The block diagram may be available to the user through a UI. The diagrams are a second way to depict the entire control path of a single parent component and identify all components within the path. Since this is accomplished with blocks and verbiage, instead of hydraulic symbols, it may be more easily understood for some individuals. While these components in the block diagrams do not have “animation” capabilities, all components are linked via hydraulic “Jump Links” back to the main supply and regulated manifolds. The block diagrams will also interact with the Failure Analysis tab to highlight components.

As will be appreciated by one skilled in the art, aspects of the disclosed invention may be embodied as a system, method or process, or computer program product. Accordingly, aspects of the disclosed invention may take the form of an entirely hardware embodiment, an entirely software embodiment (including firmware, resident software, micro-code, etc.) or an embodiment combining software and hardware aspects that may all generally be referred to herein as a “user interface,” “module,” or “system.” Furthermore, aspects of the disclosed technology may take the form of a computer program product embodied in one or more computer readable media having computer readable program code embodied thereon.

Aspects of the disclosed invention are described above (and/or below) with reference to block diagrams of methods, apparatus (systems) and computer program products according to embodiments of the invention. It will be understood that each block of the block diagrams, and combinations of blocks in the flowchart illustrations and/or block diagrams, can be implemented by computer program instructions. These computer program instructions may be provided to the processor of a computer system/server, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

A computer system/server may represent for example the machine providing functions related to simulating operating modes and failure modes when acting in the role of the providing the process. The computer system/server may also represent for example the machine providing functions related to storage of data including for example the status of an element/component and the projected state of the control system that occurs in response to a change in state of one of the elements/components selected in a user interface.

The components of the computer system/server may include one or more processors or processing units, a system memory, and a bus that couples various system components including the system memory to the processor. The computer system/server may be for example, personal computer systems, tablet devices, mobile telephone devices, server computer systems, handheld or laptop devices, multiprocessor systems, microprocessor-based systems, set top boxes, programmable consumer electronics, network PCs, dedicated network computers, and distributed cloud computing environments that include any of the above systems or devices, and the like. The computer system/server may be described in the general context of computer system executable instructions, such as program modules, being executed by the computer system. The computer system/server and auditing process(es) may be practiced in distributed cloud computing environments where tasks are performed by remote processing devices that are linked through a communications network. In a distributed cloud computing environment, program modules may be located in both local and remote computer system storage media including memory storage devices.

The computer system/server may typically include a variety of computer system readable media. Such media could be chosen from any available media that is accessible by the computer system/server, including non-transitory, volatile and non-volatile media, removable and non-removable media. The system memory could include one or more computer system readable media in the form of volatile memory, such as a random-access memory (RAM) and/or a cache memory. By way of example only, a storage system can be provided for reading from and writing to a non-removable, non-volatile magnetic media device. The system memory may include at least one program product having a set (e.g., at least one) of program modules that are configured to carry out the functions of storing element/component definitions, element/component identifications, pointers attached to a jump link that trigger a jump to a connected component from the module displaying the jump link, simulating an effect on a component in response to a user selected change in the component, simulating effects on components connected to the selected changed component, and generating reports of the control system showing component performance under simulated induced failure modes.

Persons of ordinary skill in the art may appreciate that numerous design configurations may be possible to enjoy the functional benefits of the inventive systems. Thus, given the wide variety of configurations and arrangements of embodiments of the present invention the scope of the invention is reflected by the breadth of the claims below rather than narrowed by the embodiments described above.

What is claimed is:

1. A computer processor implemented method of generating risk and reliability reports of underwater well control equipment used for offshore drilling operations, comprising:
building a library of piping and instrumentation diagrams using virtual components retrieved from a component database, for a proposed underwater well control system;
connecting the virtual components hydraulically into a simulated well control system using the library of piping and instrumentation diagrams;
determining a function for each virtual component;
simulating a test of each function for each virtual component in the simulated well control system;
associating failure modes for one or more virtual components in the simulated well control system;
for a selected virtual component in the simulated well control system, and for a selected failure mode, evaluating the selected virtual component for the selected failure mode for a symptomology and an effect on connected elements in the simulated well control system;
determining an impact on the simulated well control system based on the symptomology and the effect on connected elements; and
generate a risk assessment report based on the determined impact on the simulated well control system.

2. The method of claim 1, further comprising comparing a virtual reaction of the simulated test of each function to a stored actual system response for each function to verify an accuracy of the virtual reaction.

3. The method of claim 1, further comprising identifying connection issues between connected elements in the simulated well control system.

4. The method of claim 1, wherein:
the simulated well control system is displayed across multiple windows in sections of the proposed underwater well control system; and
the virtual components are connected across the multiple windows.

5. The method of claim 4, further comprising, for each virtual component:
identifying each other virtual component connected to the selected virtual component; and
generating a plurality of jump links from the selected virtual component to each other virtual component connected to the virtual component.

6. The method of claim 5, wherein the jump links are selectable and in response to a selection of a jump link for the selected virtual component, a display of a first window showing the selected virtual component switches to a second window showing another virtual component connected to the selected virtual component by the jump link.

7. The method of claim 1, further comprising determining a troubleshooting action for each failure mode for each virtual component.

8. The method of claim 7, further comprising generating troubleshooting decision trees based on the symptomology and the effect on connected elements during evaluation of the selected virtual component for the selected failure mode.

9. The method of claim 1, further comprising generating an operational contingency plan for every failure mode.

10. The method of claim 1, further comprising determining whether the impact on the simulated well control system will affect a Deadman Autoshear automated emergency system in the proposed underwater well control system.

11. The method of claim 1, further comprising determining whether the impact on the simulated well control system will affect an emergency disconnect sequence in the proposed underwater well control system.

12. The method of claim 1, further comprising graphically displaying the selected failure mode for the selected virtual component.

13. The method of claim 1, further comprising assigning a unique component identification to each virtual component.

14. The method of claim 13, further comprising:
generating a selectable button for the selected virtual component;
retrieving the unique component identification for the selected virtual component;
retrieving failure modes associated with the selected virtual component;
retrieving impacts on the proposed underwater well control system based on the failure modes associated with the selected virtual component;
retrieving troubleshooting actions associated with the selected virtual component based on the failure modes; and
generating the automated risk assessment report for the selected virtual component and the selected failure mode, wherein the automated risk assessment report displays the selected virtual component by the unique component identification and displays:
the retrieved impact on the proposed underwater well control system based on the failure modes associated with the selected virtual component, and
the retrieved troubleshooting actions associated with the selected virtual component based on the failure modes.

15. A computer implemented method of generating a report for an underwater well control system used for offshore drilling operations, wherein the underwater well control system comprises a plurality of backup components, the computer implemented method comprising:
connecting a plurality of virtual components into a simulated well control system that corresponds to a plurality of actual components of the underwater well control system;
simulating a test of function of the plurality of virtual components in the simulated well control system;
determining an effect of a failed virtual component on the plurality of virtual components in the simulated well control system;
determining whether the underwater well control system comprises at least a minimum capability to remain in service in accord with industry and regulatory guidance in response to a failed actual component that corresponds to the failed virtual component; and
generating the report.

16. The method of claim 15, wherein the step of generating the report further comprises programming a computer to develop an operation contingency plan for the underwater well control system to operate with the failed actual component.

17. The method of claim 15, further comprising utilizing the simulated well control system for determining an effect of the failed actual component on an emergency disconnect sequence of the underwater well control system.

18. The method of claim 15, further comprising utilizing the simulated well control system for determining an effect of the failed actual component on an autoshear function of the underwater well control system.

19. The method of claim 15, further comprising utilizing the simulated well control system for determining an effect of the failed actual component on acoustic operations of the underwater well control system.

20. The method of claim 15, further comprising determining whether the underwater well control system comprises at least the minimum capability to remain in service in accord with industry and regulatory guidance based on the effect of a plurality of failed virtual components in the simulated well control system that correspond to a plurality of failed actual components in the underwater well control system.

21. A computer implemented method of generating a report for an underwater well control system used for offshore drilling operations, wherein the underwater well control system comprises a plurality of backup components, the computer implemented method comprising:
connecting a plurality of virtual components into a simulated well control system that corresponds to a plurality of actual components connected in the underwater well control system;
simulating a test function of the plurality of virtual components in the simulated well control system;
determining an effect of a failed virtual component on the plurality of virtual components in the simulated well control system;
determining whether a blowout preventer (BOP) stack or lower marine riser package of the underwater well control system requires pulling to a surface position for repairs based on industry and regulatory guidance in response to a failed actual component that corresponds to the failed virtual component; and
when it is determined that the BOP stack or lower marine riser package of the underwater well control system does not require pulling to the surface position for repairs, then utilizing programming of a computer to develop an operation contingency plan for the underwater well control system to operate with the failed actual component.

22. The method of claim 21, further comprising utilizing the simulated well control system for determining whether the underwater well control system comprises at least a minimum capability to remain in service in accord with industry and regulatory guidance based on a simulated effect of a plurality of failed virtual components that correspond to a plurality of failed actual components.

23. The method of claim 21, further comprising utilizing the simulated well control system for determining an effect of the failed actual component on an emergency disconnect sequence of the underwater well control system.

24. The method of claim 21, further comprising utilizing the simulated well control system for determining an effect of the failed actual component on an autoshear function of the underwater well control system.

25. The method of claim 21, further comprising utilizing the simulated well control system for determining an effect of the failed actual component on acoustic operations of the underwater well control system.

26. The method of claim 21, further comprising utilizing a stored history of actual test results of operation of a plurality of actual components of the underwater well control system for comparison with a calculated operation of the plurality of virtual components in the simulated well control system.
